(19) United States
(12) Patent Application Publication
(10) Pub. No.: US 2026/0293662 A1
(43) Pub. Date: Sep. 24, 2026

(54) PHOTOSENSITIVE RESIN COMPOSITION, PATTERNED CURED PRODUCT, PRODUCTION METHOD FOR PATTERNED CURED PRODUCT, AND ELECTRIC COMPONENT

(71) Applicant: HD MICROSYSTEMS, LTD., Shinjuku-ku, Tokyo (JP)

(72) Inventors: Takumi ONUMA, Shinjuku-ku, Tokyo (JP); Satoshi ABE, Shinjuku-ku, Tokyo (JP)

(21) Appl. No.: 19/479,948

(22) PCT Filed: Oct. 24, 2023
(86) PCT No.: PCT/JP2023/038391

§ 371 Date: Oct. 29, 2025

(51) Int. Cl. H10W 20/48; C08G 73/10; G03F 7/031; G03F 7/40; H10W 20/00; H10W 74/01; H10W 74/10; H10W 74/47

(52) U.S. Cl. CPC H10W 20/48; C08G 73/10; G03F 7/031; G03F 7/40; H10W 20/082; H10W 74/01; H10W 74/147; H10W 74/47

(57) ABSTRACT

A photosensitive resin composition includes a polyimide precursor having a polymerizable unsaturated bond, and a crosslinking agent having a vinyl group accompanied by a hydrocarbon group located at an allyl position.

### TECHNICAL FIELD

The present disclosure relates to a photosensitive resin composition, a patterned cured product, a method for producing a patterned cured product, and an electronic component.

### BACKGROUND ART

Polyimides, polybenzoxazoles, and the like, which have superior heat resistance, electric properties, mechanical properties, and the like, have thus far been used as surface protective films and interlayer insulating films for semiconductor elements. In recent years, photosensitive resin compositions having photosensitivity imparted to the resins have been used, and use of such photosensitive resin compositions enables simplification of production processes for patterned cured products, and shortening of complicated production steps (refer to, for example, Patent Document 1).

### PRIOR ART DOCUMENT

### Patent Document

Patent Document 1: Japanese Patent Application Laid-open (JP-A) No. 2009-265520

### SUMMARY OF INVENTION

### Problem to be Solved by Invention

As the performance of semiconductor elements is heightened, re-distribution layers are made finer, and polyimides that form electrically insulating films are also desired to have capability of achieving high resolution.

In consideration of the aforementioned existing circumstances, an object of one embodiment of the present disclosure is to provide of a photosensitive resin composition capable of achieving a higher resolution, a cured product obtained using the photosensitive resin composition, a method of producing a patterned cured product using the photosensitive resin composition, and an electronic component obtained using the photosensitive resin composition.

### Means for Solving the Problem

Specific means for achieving the above object include the following.
<1> A photosensitive resin composition, including a polyimide precursor having a polymerizable unsaturated bond, and a crosslinking agent having a vinyl group accompanied by a hydrocarbon group located at an allyl position.
<2> The photosensitive resin composition according to <1>, wherein the polyimide precursor having a polymerizable unsaturated bond includes a structural unit represented by the following Formula (1):

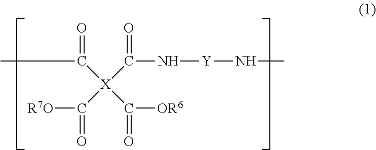

wherein, in Formula (1), X represents a tetravalent organic group; Y represents a divalent organic group; each of R⁶ and R⁷ independently represents a hydrogen atom or a monovalent organic group, and at least one of R⁶ or R⁷ has a polymerizable unsaturated bond.
<3> The photosensitive resin composition according to <1> or <2>, further including at least one selected from the group consisting of a photopolymerization initiator, a sensitizer, a ultraviolet absorber, a stabilizer, and a solvent.
<4> A method of producing a patterned cured product, the method including:
a step of applying the photosensitive resin composition according to any one of <1> to <3> to a substrate, and drying the photosensitive resin composition, thereby forming a photosensitive resin film;
a step of patternwise exposing the photosensitive resin film, thereby obtaining a resin film;
a step of developing the resin film after patternwise exposure with a developer, thereby obtaining a patterned resin film, and
a step of heating the patterned resin film.
<5> A patterned cured product, which is obtained by curing the photosensitive resin composition according to any one of <1> to <3>.
<6> The patterned cured product according to <5>, wherein the patterned cured product is used as an interlayer insulating film, a cover-coat layer, or a surface protective film.
<7> An electronic component, including the patterned cured product according to <5> or <6>.

### Advantageous Effect of Invention

According to one embodiment of the present disclosure, a photosensitive resin composition capable of achieving a higher resolution, a cured product obtained using the photosensitive resin composition, a method of producing a patterned cured product using the photosensitive resin composition, and an electronic component obtained using the photosensitive resin composition, can be provided.

### BRIEF DESCRIPTION OF THE DRAWING

FIG. 1 is a process diagram for producing an electronic component according to one embodiment of the present disclosure.

### MODES OR CARRYING OUT INVENTION

Modes for carrying out the present disclosure will be described in detail below. However, the present disclosure is not limited to the embodiments described below. In the embodiments described below, the components (including element steps and the like) thereof are not essential unless explicitly stated as essential. The same applies to numerical values and numerical ranges, and the numerical values and ranges do not limit the present disclosure.

In the present disclosure, the term “step” includes not only a step that is independent of other steps, but also a step that cannot be clearly distinguished from other steps as long as the purpose of the step of interest is achieved.

In the present disclosure, numerical ranges indicated using “to” include the numerical values before and after “to” as the minimum and maximum values.

When numerical ranges are described in stepwise manner in the present disclosure, the upper or lower limit value described in one numerical range may be replaced with the upper or lower limit value of another numerical range in the stepwise description. Furthermore, in any numerical range described in the present disclosure, the upper or lower limit of the numerical range may be replaced with a value indicated in the Examples.

In the present disclosure, each component may include plural substances corresponding thereto. In a case in which plural substances each corresponding to a particular component are present in a composition, the content ratio or content of the component means the total content ratio or total content of the plural substances present in the composition, unless otherwise specified.

In the present disclosure, the scope of the terms “layer” and “film” encompasses a case in which, as a result of observation of a region in which the layer or film is present, it is observed that the layer or film is formed over the entire region, as well as a case in which it is observed that the layer or film is formed only in a part or parts of the region.

In the present disclosure, the term “(meth)acryloyl group” refers to at least one of an acryloyl group or a methacryloyl group, and the term “(meth)acryloyloxy group” refers to at least one of an acryloyloxy group or a methacryloyloxy group.

In the present disclosure, the average thickness of the layer or film means a value that is obtained as an arithmetic average value of measured thicknesses of the layer or film of interest at five points.

The thickness of the layer or film can be measured using, for example, a micrometer, a scanning stylus meter, or a light interference film thickness measuring device. In the present disclosure, a light interference film thickness measuring device is used for measurement in a case in which the thickness of the layer or film can be directly measured. In a case in which the thickness of one layer or the total thickness of plural layers is to be measured, measurement may be made by observing a cross-section of an object to be measured, using an electron microscope.

### <Photosensitive Resin Composition>

The photosensitive resin composition according to the present disclosure includes a polyimide precursor having a polymerizable unsaturated bond, and a crosslinking agent having a vinyl group accompanied by a hydrocarbon group located at an allyl position. The “polyimide precursor having a polymerizable unsaturated bond” is hereinafter also referred to as the “unsaturated polyimide precursor”, and the “crosslinking agent having a vinyl group accompanied by a hydrocarbon group located at an allyl position” is hereinafter also referred to as the “vinyl crosslinking agent”.

The photosensitive resin composition having the above-described configuration is capable of achieving a higher resolution. The reason therefor is not clear, but we surmise that the reason is as follows.

In conventional photosensitive resin compositions containing the unsaturated polyimide precursor, a polymerizable monomer or a crosslinking agent is used which does not have a vinyl group accompanied by a hydrocarbon group located at an allyl position, and which has a (meth)acryloyl group. Compared to this (meth)acryloyl-containing monomer or crosslinking agent, the vinyl crosslinking agent has a reduced crosslinking reaction activity. As a result of this, the photosensitive resin composition that includes the vinyl crosslinking agent experiences reduced crosslinking caused by unintended circumvention of exposure light, generation of residues and the like is reduced, and, therefore, pattern forming properties improve and resolution can be heightened. We surmise the foregoing mechanism.

Respective components contained in the photosensitive resin composition according to the present disclosure are described below. The photosensitive resin composition according to the present disclosure is preferably a negative-working photosensitive resin composition.

### (Unsaturated Polyimide Precursor)

The photosensitive resin composition according to the present disclosure includes a polyimide precursor having a polymerizable unsaturated bond (hereinafter sometimes referred to as the “unsaturated polyimide precursor”).

The polymerizable unsaturated bond is, for example, a carbon-carbon double bond.

The unsaturated polyimide precursor may be synthesized using a tetracarboxylic dianhydride and a diamine compound. The unsaturated polyimide precursor may alternatively be synthesized using a tetracarboxylic acid instead of a tetracarboxylic dianhydride.

The unsaturated polyimide precursor preferably includes a structural unit represented by the following Formula (1).

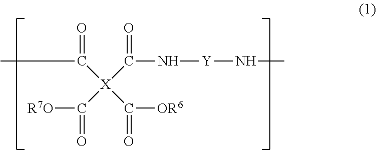

In Formula (1), X represents a tetravalent organic group; Y represents a divalent organic group, each of R⁶ and R⁷ independently represents a hydrogen atom or a monovalent organic group, and at least one of R⁶ or R⁷ has a polymerizable unsaturated bond.

The unsaturated polyimide precursor may include plural structural units each represented by Formula (1), and X's in the plural structural units may be the same or different, Y's in the plural structural units may be the same or different, R⁶'s in the plural structural units may be the same or different, and R⁷'s in the plural structural units may be the same or different.

As far as each of R⁶ and R⁷ independently represents a hydrogen atom or a monovalent organic group, the combination of the structures represented by R⁶ and R⁷ is not particularly limited. In an example, at least one of R⁶ or R⁷ is a hydrogen atom, and the other of R⁶ or R⁷ may be a monovalent organic group, which will be detailed later. In another example, R⁶ and R⁷ represent monovalent organic groups that may be the same as each other or different from each other. In a case in which the unsaturated polyimide precursor includes plural structural units each represented by Formula (1) as mentioned above, the combination of the structures represented by R⁶ and R⁷ in each structural unit may be the same as each other or different from each other.

In Formula (1), the tetravalent organic group represented by X preferably has from 4 to 25 carbon atoms, more preferably has from 5 to 13 carbon atoms, and still more preferably has from 6 to 12 carbon atoms.

The tetravalent organic group represented by X may include an aromatic ring. Examples of the aromatic ring include aromatic hydrocarbon groups (in which the number of carbon atoms that form the aromatic ring is, for example, from 6 to 20), and aromatic heterocyclic groups (in which the number of atoms that form the heterocycle is, for example, from 5 to 20). The tetravalent organic group represented by X is preferably an aromatic hydrocarbon group. Examples of the aromatic hydrocarbon group include a benzene ring, a naphthalene ring, and a phenanthrene ring.

In a case in which the tetravalent organic group represented by X includes an aromatic ring, each aromatic ring may have a substituent or may be unsubstituted. Examples of a substituent on the aromatic ring include an alkyl group, a fluorine atom, a halogenated alkyl group, a hydroxy group, and an amino group.

When the tetravalent organic group represented by X includes a benzene ring, the tetravalent organic group represented by X preferably includes from 1 to 4 benzene rings, more preferably includes from 1 to 3 benzene rings, and still more preferably includes 1 or 2 benzene rings.

When the tetravalent organic group represented by X includes two or more benzene rings, each connection between benzene rings may be a single bond, or a connecting group such as an alkylene group, a halogenated alkylene group, a carbonyl group, a sulfonyl group, an ether bond (—O—), a sulfide bond (—S—), a silylene bond (—Si(R^{A})₂— in which each of two R^{A}'s independently represents a hydrogen atom, an alkyl group, or a phenyl group), a siloxane bond (—O—(Si(R^{B})₂—O—)ₙ in which each of two R^{B}'s independently represents a hydrogen atom, an alkyl group, or a phenyl group, and n represents an integer of 1 or 2 or greater), or a combined connecting group obtained by combining at least two of these connecting groups. Two benzene rings may be connected at two sites by at least one of a single bond or a connecting group, so as to form a five-membered or six-membered ring that includes the connecting group and that is located between the two benzene rings.

In Formula (1), the —COOR⁶ group and the —CONH— group are preferably located at ortho-positions relative to each other, and the —COOR⁷ group and the —CO— group are preferably located at ortho-positions relative to each other.

Specific examples of the tetravalent organic group represented by X include the groups represented by the following Formulae (A) to (F). Among them, a group represented by Formula (E) is preferable, a group represented by Formula (E) in which C represents a group containing an ether bond is more preferable, a group represented by Formula (E) in which C represents an ether bond is still more preferable, from the viewpoint that an insulating film having excellent flexibility and reduced generation of voids at joining interface can be obtained. Formula (F) represents a structure corresponding to a structure represented by Formula (E) in which C represents a single bond. The present disclosure is not limited to the following specific examples.

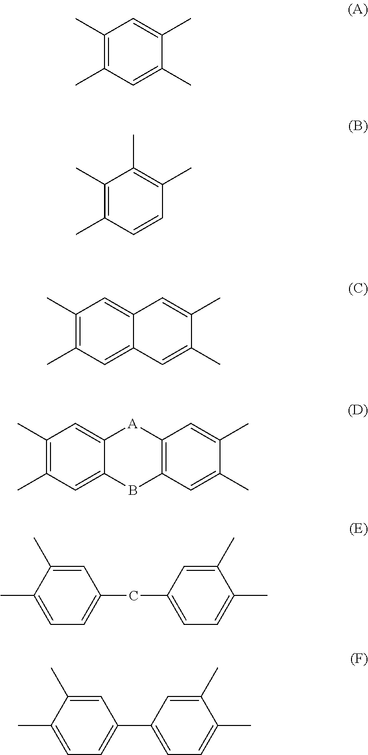

In Formula (D), each of A and B independently represents a single bond or a divalent group that does not conjugate with a benzene ring, provided that A and B cannot both be single bonds. Examples of the divalent group that does not conjugate with a benzene ring include a methylene group, a halogenated methylene group, a halogenated methylmethylene group, a carbonyl group, a sulfonyl group, an ether bond (—O—), a sulfide bond (—S—), and a silylene bond (—Si(R^{A})₂ in which each of two R^{A}'s independently represents a hydrogen atom, an alkyl group, or a phenyl group). Among them, each of A and B independently represents preferably a methylene group, a bis(trifluoromethyl)methylene group, a difluoromethylene group, an ether bond, a sulfide bond, or the like, and more preferably an ether bond.

In Formula (E), C represents a single bond, an alkylene group, a halogenated alkylene group, a carbonyl group, a sulfonyl group, an ether bond (—O—), a sulfide bond (—S—), a phenylene group, an ester bond (—O—C(═O)—), a silylene bond (—Si(R^{A})₂ in which each of two R^{A}'s independently represents a hydrogen atom, an alkyl group, or a phenyl group), a siloxane bond (—O—(Si(R^{B})₂—O—)ₙ in which each of two R^{B}'s independently represents a hydrogen atom, an alkyl group, or a phenyl group, and n represents an integer of 1 or 2 or greater), or a divalent group obtained by combining at least two of these groups. C preferably includes an ether bond, and is preferably an ether bond.

Further, C may include a structure represented by the following Formula (C1).

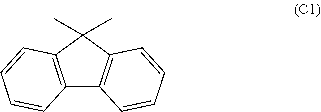

In Formula (E), the alkylene group represented by C is preferably an alkylene group having from 1 to 10 carbon atoms, more preferably an alkylene group having from 1 to 5 carbon atoms, and still more preferably an alkylene group having 1 or 2 carbon atoms.

Specific examples of the alkylene group represented by C in Formula (E) include: a linear alkylene group such as a methylene group, an ethylene group, a trimethylene group, a tetramethylene group, a pentamethylene group, or a hexamethylene group; and a branched chain alkylene group such as a methylmethylene group, a methylethylene group, an ethylmethylene group, a dimethylmethylene group, a 1,1-dimethylethylene group, a 1-methyltrimethylene group, a 2-methyltrimethylene group, an ethylethylene group, a 1-methyltetramethylene group, a 2-methyltetramethylene group, a 1-ethyltrimethylene group, a 2-ethyltrimethylene group, a 1,1-dimethyltrimethylene group, a 1,2-dimethyltrimethylene group, a 2,2-dimethyltrimethylene group, a 1-methylpentamethylene group, a 2-methylpentamethylene group, a 3-methylpentamethylene group, a 1-ethyltetramethylene group, a 2-ethyltetramethylene group, a 1,1-dimethyltetramethylene group, a 1,2-dimethyltetramethylene group, a 2,2-dimethyltetramethylene group, a 1,3-dimethyltetramethylene group, a 2,3-dimethyltetramethylene group, or a 1,4-dimethyltetramethylene group. Among them, a methylene group is preferable.

In Formula (E), the halogenated alkylene group represented by C is preferably a halogenated alkylene group having from 1 to 10 carbon atoms, more preferably a halogenated alkylene group having from 1 to 5 carbon atoms, and still more preferably a halogenated alkylene group having from 1 to 3 carbon atoms.

In Formula (E), a specific example of the halogenated alkylene group represented by C is an alkylene group in which at least one hydrogen atom contained in the alkylene group represented by C in Formula (E) is replaced by a halogen atom such as a fluorine atom or a chlorine atom. Among them, a fluoromethylene group, a difluoromethylene group, and a hexafluorodimethylmethylene group, and the like are preferable.

The alkyl group represented by R^{A} or R^{B} contained in the silylene bond or the siloxane bond is preferably an alkyl group having from 1 to 5 carbon atoms, more preferably an alkyl group having from 1 to 3 carbon atoms, and still more preferably an alkyl group having 1 or 2 carbon atoms. Specific examples of the alkyl group represented by R^{A} or R^{B} include a methyl group, an ethyl group, an n-propyl group, an isopropyl group, an n-butyl group, an isobutyl group, an s-butyl group, and a t-butyl group.

Specific examples of the tetravalent organic group represented by X include the groups represented by Formulae (J) to (O).

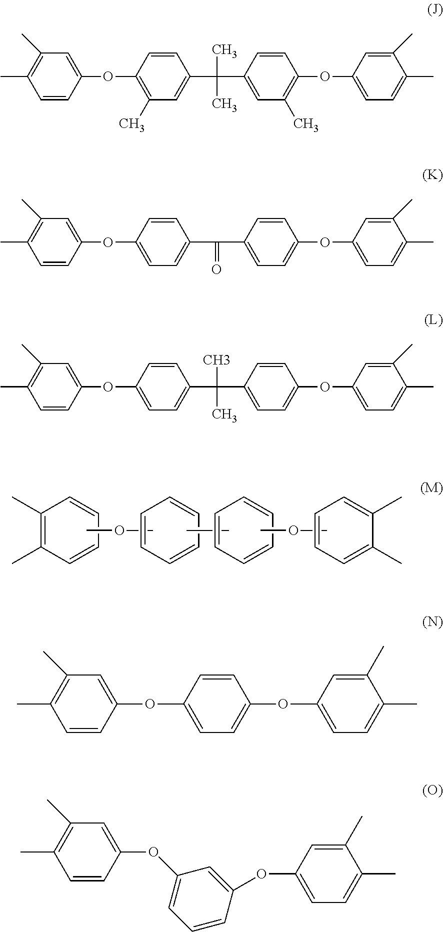

In Formula (1), the divalent organic group represented by Y has preferably from 4 to 25 carbon atoms, more preferably from 6 to 20 carbon atoms, and still more preferably from 12 to 18 carbon atoms.

The skeleton of the divalent organic group represented by Y may have the same specifics as those of the skeleton of the tetravalent organic group represented by X, preferable skeletons of the divalent organic group represented by Y may be the same as the preferable skeletons for the tetravalent organic group represented by X. The skeleton of the divalent organic group represented by Y may be a structure obtained by substituting two binding sites of the tetravalent organic group represented by X with an atom (for example, a hydrogen atom) or functional group (for example, an alkyl group).

The divalent organic group represented by Y may be a divalent aliphatic group or a divalent aromatic group. From the viewpoint of heat resistance, the divalent organic group represented by Y is preferably a divalent aromatic group. Examples of the divalent aromatic group include a divalent aromatic hydrocarbon group (in which the number of carbon atoms that form the aromatic ring is from 6 to 20) and a divalent aromatic heterocyclic group (in which the number of carbo atoms that form a heterocycle is from 5 to 20), and a divalent aromatic hydrocarbon group is preferable.

Specific examples of the divalent aromatic group represented by Y include groups represented by the following Formulae (G) and (H). Among them, from the viewpoint that an electrically insulating film having excellent flexibility and which experiences reduced generation of voids at joining interface can be obtained, a group represented by Formula (H) is preferable, and, in Formula (H), D is more preferably a single bond or a group containing an ether group, still more preferably a single bond or a group containing an ether bond, particularly preferably a group containing an ether bond, and quite preferably an ether bond.

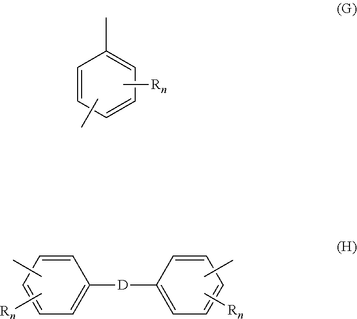

In Formulae (G) to (H), each R independently represents an alkyl group, an alkoxy group, a halogenated alkyl group, a phenyl group, or a halogen atom, and each n independently represents an integer from 0 to 4.

In Formula (H), D represents a single bond, an alkylene group, a halogenated alkylene group, a carbonyl group, a sulfonyl group, an ether bond (—O—), a sulfide bond (—S—), a phenylene group, an ester bond (—O—C(═O)—), a silylene bond (—Si(R^{A})₂ in which each of two R^{A}'s independently represents a hydrogen atom, an alkyl group, or a phenyl group), a siloxane bond (—O—(Si(R^{B})₂—O—)ₙ in which each of two R^{B}'s independently represents a hydrogen atom, an alkyl group, or a phenyl group, and n represents an integer of 1 or 2 or greater), or a divalent group obtained by combining at least two of these groups. Further, D may be a structure represented by Formula (C1). Specific examples of D in Formula (H) include the specific examples of C in Formula (E).

Each D in Formula (H) independently represents preferably a single bond, an ether bond, a group containing an ether bond and a phenylene group, a group containing an ether bond, a phenylene group, and an alkylene group, or the like.

The alkyl group represented by R in Formulae (G) to (H) is preferably an alkyl group having from 1 to 10 carbon atoms, more preferably an alkyl group having from 1 to 5 carbon atoms, and still more preferably an alkyl group having 1 or 2 carbon atoms.

Specific examples of the alkyl group represented by R in Formulae (G) to (H) include a methyl group, an ethyl group, an n-propyl group, an isopropyl group, an n-butyl group, an isobutyl group, an s-butyl group, and a t-butyl group.

The alkoxy group represented by R in Formulae (G) to (H) is preferably an alkoxy group having from 1 to 10 carbon atoms, more preferably an alkoxy group having from 1 to 5 carbon atoms, and still more preferably an alkoxy group having 1 or 2 carbon atoms.

Specific examples of the alkoxy group represented by R in Formulae (G) to (H) include a methoxy group, an ethoxy group, an n-propoxy group, an isopropoxy group, an n-butoxy group, an isobutoxy group, an s-butoxy group, and a t-butoxy group.

The halogenated alkyl group represented by R in Formulae (G) to (H) is preferably a halogenated alkyl group having from 1 to 5 carbon atoms, more preferably a halogenated alkyl group having from 1 to 3 carbon atoms, and still more preferably a halogenated alkyl group having 1 or 2 carbon atoms.

A specific example of the halogenated alkyl group represented by R in Formulae (G) to (H) is an alkyl group represented by R in Formulae (G) to (H) in which at least one hydrogen atom contained therein has been replaced by a halogen atom such as a fluorine atom or a chlorine atom. Among them, a fluoromethyl group, a difluoromethyl group, a trifluoromethyl group, and the like are preferable.

In Formulae (G) to (H), each n independently represents preferably from 0 to 2, more preferably 0 or 1, and still more preferably 0.

Specific examples of the divalent aliphatic group represented by Y include a linear or branched chain alkylene group, a cycloalkylene group, a divalent group having a polyalkyleneoxide structure.

The linear or branched chain alkylene group represented by Y is preferably an alkylene group having from 1 to 20 carbon atoms, more preferably an alkylene group having from 1 to 15 carbon atoms, and still more preferably an alkylene group having from 1 to 10 carbon atoms.

Specific examples of the alkylene group represented by Y include a tetramethylene group, a hexamethylene group, a heptamethylene group, an octamethylene group, a nonamethylene group, a decamethylene group, an undecamethylene group, a dodecamethylene group, a 2-methylpentamethylene group, a 2-methylhexamethylene group, a 2-methylheptamethylene group, a 2-methyloctamethylene group, a 2-methylnonamethylene group, and a 2-methyldecamethylene group.

The cycloalkylene represented by Y is preferably a cycloalkylene group having from 3 to 10 carbon atoms, and more preferably a cycloalkylene group having from 3 to 6 carbon atoms.

Specific examples of the cycloalkylene represented by Y include a cyclopropylene group and a cyclohexylene group.

The unit structure contained in the divalent group having a polyalkyleneoxide structure represented by Y is preferably an alkylene oxide structure having from 1 to 10 carbon atoms, more preferably an alkyleneoxide group having from 1 to 8 carbon atoms, and still more preferably an alkyleneoxide group having from 1 to 4 carbon atoms. Among them, the polyalkyleneoxide structure is preferably a polyethyleneoxide structure or a polypropyleneoxide structure. The alkylene group in the alkyleneoxide structure may be linear or branched. The polyalkyleneoxide structure may include only one kind of structural unit or may include two or more kinds of structural unit.

The divalent organic group represented by Y may be a divalent group having a polysiloxane structure. The divalent group having a polysiloxane structure represented by Y is, for example, a divalent group having a polysiloxane structure in which a silicon atom in the polysiloxane structure is bonded to a hydrogen atom, an alkyl group having from 1 to 20 carbon atoms, or an aryl group having from 6 to 18 carbon atoms.

Specific examples of the alkyl group having from 1 to 20 carbon atoms bonded to a silicon atom in the polysiloxane structure include a methyl group, an ethyl group, an n-propyl group, an isopropyl group, an n-butyl group, a t-butyl group, an n-octyl group, a 2-ethylhexyl group, and an n-dodecyl group. Among them, a methyl group is preferable. The aryl group having from 6 to 18 carbon atoms bonded to a silicon atom in the polysiloxane structure may be unsubstituted or may be substituted by a substituent. In a case in which the aryl group is substituted by a substituent, specific examples of the substituent include a halogen atom, an alkoxy group, and a hydroxy group. Specific examples of the aryl group having from 6 to 18 carbon atoms include a phenyl group, a naphthyl group, and a benzyl group. Among them, a phenyl group is preferable.

The polysiloxane structure may include only one kind of alkyl group having from 1 to 20 carbon atoms or aryl group having from 6 to 18 carbon atoms, or may include two or more kinds of alkyl groups having from 1 to 20 carbon atoms or aryl groups having from 6 to 18 carbon atoms.

The silicon atom contained in the divalent group represented by Y and having a polysiloxane structure may be bonded to an NH group in Formula (1), for example, via an alkylene group such as a methylene group or an ethylene group, or an arylene group such as a phenylene group.

The group represented by Formula (G) is preferably a group represented by the following Formula (G′). The group represented by Formula (H) is preferably a group represented by the following Formula (H′), Formula (H″), or Formula (H′″). The group represented by Formula (H) is more preferably a group represented by the following Formula (H′) or Formula (H″), from the viewpoint that the group has a flexible skeleton and an excellent joining property.

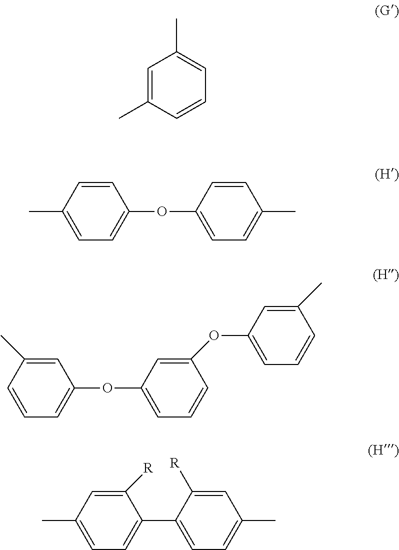

In Formula (H′″), each R independently represents an alkyl group, an alkoxy group, a halogenated alkyl group, a phenyl group, or a halogen atom. R is preferably an alkyl group, and more preferably a methyl group.

In Formula (1), the combination of the tetravalent organic groups represented by X's and the divalent organic groups represented by Y's is not particularly limited. Examples of the combination of the tetravalent organic groups represented by X's and the divalent organic groups represented by Y's include the following:
a combination in which each X represents a group represented by Formula (E) and each Y represents a group represented by Formula (H);
a combination in which each X represents a group represented by Formula (F) and each Y represents a group represented by Formula (H);
a combination in which each X represents a group represented by Formula (E) and Y's represent groups represented by Formula (G) and groups represented by Formula (H);
a combination in which X's represent groups represented by Formula (A) and groups represented by Formula (E) and each Y represents a group represented by Formula (H); and
a combination in which each X represents a group represented by Formula (A) and each Y represents a group represented by Formula (H).

Each of R⁶ and R⁷ independently represents a hydrogen atom or a monovalent organic group, provided that at least one of R⁶ or R⁷ has a polymerizable unsaturated bond. The monovalent organic group is preferably an aliphatic hydrocarbon group having from 1 to 4 carbon atoms or an organic group having an unsaturated double bond, more preferably any one of a group represented by the following Formula (2), an ethyl group, an isobutyl group, or a t-butyl group, and still more preferably includes an aliphatic hydrocarbon group having 1 or 2 carbon atoms or a group represented by the following Formula (2). In this case, at least one of R⁶ or R⁷ is a group represented by Formula (2).

When the monovalent organic group includes an organic group having an unsaturated double bond, preferably a group represented by the following Formula (2), there is a tendency that i-line transparency is high, and that a superior cured product can be formed even by low temperature curing at 400° C. or lower. When the monovalent organic group includes an organic group having an unsaturated double bond, preferably a group represented by the following Formula (2), at least some of unsaturated double bond portions are eliminated through imidization.

Specific examples of the aliphatic hydrocarbon group having from 1 to 4 carbon atoms include a methyl group, an ethyl group, an n-propyl group, an isopropyl group, an n-butyl group, and a t-butyl group. Among them, an ethyl group, an isobutyl group, and a t-butyl group are preferable.

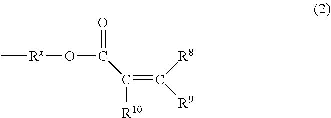

In Formula (2), each of R⁸ to R¹⁰ independently represents a hydrogen atom or an aliphatic hydrocarbon group having from 1 to 3 carbon atoms, and R^{X} represents a divalent connecting group.

The number of carbon atoms of the aliphatic hydrocarbon group represented by any one of R⁸ to R¹⁰ in Formula (2) is from 1 to 3, and preferably 1 or 2. Specific examples of the aliphatic hydrocarbon group represented by any one of R⁸ to R¹⁰ include a methyl group, an ethyl group, an n-propyl group, and an isopropyl group, and a methyl group is preferable.

In Formula (2), the combination of R⁸ to R¹⁰ is preferably a combination in which R⁸ and R⁹ each represent a hydrogen atom, and in which R¹⁰ represents a hydrogen atom or a methyl group.

In Formula (2), R^{x} represents a divalent connecting group, and preferably a hydrocarbon group having from 1 to 10 carbon atoms. The hydrocarbon group having from 1 to 10 carbon atoms is, for example, a linear or branched chain alkylene group.

The number of carbon atoms of R^{x} is preferably from 1 to 10, more preferably from 2 to 5, and still more preferably 2 or 3.

In Formula (1), at least one of R⁶ or R⁷ is preferably a group represented by Formula (2), and it is more preferable that both of R⁶ and R⁷ are groups represented by Formula (2).

When the unsaturated polyimide precursor includes a compound including a structural unit represented by Formula (1), the proportion of R⁶ and R⁷ structures that are groups represented by Formula (2) relative to all R⁶ and R⁷ structures contained in all structural units of the compound is preferably higher than or equal to 60 mol %, more preferably higher than or equal to 70 mol %, and still more preferably higher than or equal to 80 mol %. The upper limit value is not particularly limited, and may be 100 mol %.

The foregoing proportion may be higher than or equal to 0 mol % and lower than 60 mol %.

The group represented by Formula (2) is preferably a group represented by the following Formula (2′).

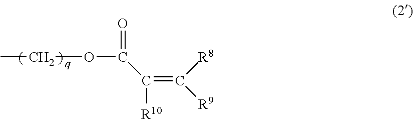

In Formula (2′), each of R⁸ to R¹⁰ independently represents a hydrogen atom or an aliphatic hydrocarbon group having from 1 to 3 carbon atoms, and q represents an integer from 1 to 10.

In Formula (2′), q represents an integer from 1 to 10, more preferably an integer from 2 to 5, and still more preferably 2 or 3.

The content ratio of structural units represented by Formula (1) contained in the compound including a structural unit represented by Formula (1) is preferably higher than or equal to 60 mol %, more preferably higher than or equal to 70 mol %, and still more preferably higher than or equal to 80 mol %, with respect to all structural units. The upper limit value of the foregoing content ratio is not particularly limited, and may be 100 mol %.

The unsaturated polyimide precursor may be synthesized using a tetracarboxylic dianhydride and a diamine compound. In this case, in Formula (1), X corresponds to a residue derived from the tetracarboxylic dianhydride, and Y corresponds to a residue derived from the diamine compound. The unsaturated polyimide precursor may alternatively be synthesized using a tetracarboxylic acid instead of a tetracarboxylic dianhydride.

Specific examples of the tetracarboxylic dianhydride include pyromellitic dianhydride, 2,3,6,7-naphthalenetetracarboxylic dianhydride, 3,3′,4,4′-biphenyltetracarboxylic dianhydride, 3,3′,4,4′-biphenyl ether tetracarboxylic dianhydride, 3,3′,4,4′-benzophenone tetracarboxylic dianhydride, 1,2,5,6-naphthalene tetracarboxylic dianhydride, 2,3,5,6-pyridine tetracarboxylic dianhydride, 1,4,5,8-naphthalene tetracarboxylic dianhydride, 3,4,9,10-perylene tetracarboxylic dianhydride, m-terphenyl-3,3′,4,4′-tetracarboxylic dianhydride, p-terphenyl-3,3′,4,4′-tetracarboxylic dianhydride, 1,1,4,4′-(4,4′-isopropylidene diphenoxy)diphthalic anhydride, 4,4′-oxydiphthalic anhydride, 1,3,3,3-hexafluoro-2,2-bis(2,3-dicarboxyphenyl)propane dianhydride, 1,1,1,3,3,3-hexafluoro-2,2-bis(3,4-dicarboxyphenyl)propane dianhydride, 2,2-bis(2,3-dicarboxyphenyl)propane dianhydride, 2,2-bis(3,4-dicarboxyphenyl)propane dianhydride, 2,2-bis{4′-(2,3-dicarboxyphenoxy)phenyl}propane dianhydride, 2,2-bis{4′-(3,4-dicarboxyphenoxy)phenyl}propane dianhydride, 1,1,1,3,3,3-hexafluoro-2,2-bis{4′-(2,3-dicarboxyphenoxy)phenyl}propane dianhydride, 1,1,1,3,3,3-hexafluoro-2,2-bis{4′-(3,4-dicarboxyphenoxy)phenyl}propane dianhydride, 4,4′-oxydiphthalic dianhydride, 4,4′-sulfonyldiphthalic dianhydride, 9,9-bis(3,4-dicarboxyphenyl) fluorene dianhydride, cyclopentanone bisspironorbornane tetracarboxylic dianhydride, and 2,2-bis{4-(4′-phenoxy)phenyl}propanetetracarboxylic dianhydride.

Among them, the tetracarboxylic dianhydride is preferably at least one selected from the group consisting of 3,3′,4,4′-biphenyl ether tetracarboxylic dianhydride, pyromellitic dianhydride, 4,4′-oxydiphthalic anhydride, and 3,3′,4,4′-biphenyltetracarboxylic dianhydride, and more preferably at least one selected from the group consisting of pyromellitic dianhydride and 4,4′-oxydiphthalic anhydride, and, from the viewpoint of joining at low temperatures, it is still more preferable that 3,3′,4,4′-biphenyl ether tetracarboxylic dianhydride is contained.

Only one tetracarboxylic dianhydride may be used, or two or more tetracarboxylic dianhydrides may be used together.

Specific examples of the diamine compound include 2,2′-dimethylbiphenyl-4,4′-diamine, 2,2′-bis(trifluoromethyl)-4,4′-diaminobiphenyl, 2,2′-difluoro-4,4′-diaminobiphenyl, p-phenylene diamine, m-phenylene diamine, p-xylylene diamine, m-xylylene diamine, 1,5-diaminonaphthalene, benzidine, 4,4′-diaminodiphenyl ether, 3,4′-diaminodiphenyl ether, 3,3′-diaminodiphenyl ether, 2,4′-diaminodiphenyl ether, 2,2′-diaminodiphenyl ether, 4,4′-diaminodiphenylsulfone, 3,4′-diaminodiphenylsulfone, 3,3′-diaminodiphenylsulfone, 2,4′-diaminodiphenylsulfone, 2,2′-diaminodiphenylsulfone, 4,4′-diaminodiphenylsulfide, 3,4′-diaminodiphenylsulfide, 3,3′-diaminodiphenylsulfide, 2,4′-diaminodiphenylsulfide, 2,2′-diaminodiphenylsulfide, o-tolidine, o-tolidinesulfone, 4,4′-methylene bis(2,6-diethylaniline), 4,4′-methylene bis(2,6-diisopropylaniline), 2,4-diaminomesitylene, 1,5-diaminonaphthalene, 4,4′-benzophenone diamine, bis-{4-(4′-aminophenoxy)phenyl}sulfone, 2,2-bis{4-(4′-aminophenoxy)phenyl}propane, 3,3′-dimethyl-4,4′-diaminodiphenylmethane, 3,3′,5,5′-tetramethyl-4,4′-diaminodiphenylmethane, bis{4-(3′-aminophenoxy)phenyl}sulfone, 2,2-bis(4-aminophenyl)propane, 9,9-bis(4-aminophenyl) fluorene, 1,3-bis(3-aminophenoxy)bezene, 1,4-diaminobutane, 1,6-diaminohexane, 1,7-diaminoheptane, 1,8-diaminooctane, 1,9-diaminononane, 1,10-diaminodecane, 1,11-diaminoundecane, 1,12-diaminododecane, 2-methyl-1,5-diaminopentane, 2-methyl-1,6-diaminohexane, 2-methyl-1,7-diaminoheptane, 2-methyl-1,8-diaminooctane, 2-methyl-1,9-diaminononane, 2-methyl-1,10-diaminodecane, 1,4-cyclohexane diamine, 1,3-cyclohexane diamine, and diaminopolysiloxane. As diamine compounds, 2,2′-dimethylbiphenyl-4,4′-diamine, m-phenylenediamine, 4,4′-diaminodiphenyl ether, and 1,3-bis(3-aminophenoxy)benzene are preferable.

Among them, the diamine compound is preferably at least one selected from the group consisting of 2,2′-dimethylbiphenyl-4,4′-diamine, 4,4′-diaminodiphenyl ether, m-phenylenediamine, and 1,3-bis(3-aminophenoxy)benzene, and, from the viewpoint of having a flexible skeleton and an excellent adhesion property, is more preferably at least one selected from the group consisting of 4,4′-diaminodiphenyl ether, 1,3-bis(3-aminophenoxy)benzene, and 2,2-bis{4-(4′-aminophenoxy)phenyl}propane.

Only one diamine compound may be used, or two or more diamine compounds may be used together.

The compound A which includes a structural unit represented by Formula (1) and in which at least one of R⁶ or R⁷ in Formula (1) is a monovalent organic group can be obtained by the following method (a) or (b):
(a) allowing a tetracarboxylic dianhydride (preferably a tetracarboxylic dianhydride represented by the following Formula (8)) and a compound expressed as R—OH to react with each other in an organic solvent to form a diester derivative, and allowing the diester derivative and a diamine compound expressed as H₂N—Y—NH₂ to undergo a condensation reaction;
(b) allowing a tetracarboxylic dianhydride and a diamine compound expressed as H₂N—Y—NH₂ to react with each other in an organic solvent to obtain a polyamide acid solution, and adding a compound expressed as R—OH to the polyamide acid solution so as to cause a reaction in an organic solvent, thereby introducing an ester group.

In order to make at least one of R⁶ or R⁷ in Formula (1) have a polymerizable unsaturated bond, at least one R—OH compound in which R has a polymerizable unsaturated bond is used.

Here, Y in the diamine compound expressed as H₂N—Y—NH₂ has the same specifics as those of Y in Formula (1), and specific examples and preferable examples thereof are also the same as those of Y in Formula (1). Further, R in the compound expressed as R—OH represents a monovalent organic group, and specific examples and preferable examples thereof are the same as those of the monovalent organic group represented by R⁶ or R⁷ in Formula (1).

The tetracarboxylic dianhydride represented by Formula (8) may be used singly, or in combination of two or more thereof. The diamine compound expressed as H₂N—Y—NH₂ may be used singly, or in combination of two or more thereof. The compound expressed as R—OH may be used singly, or in combination of two or more thereof.

Examples of the organic solvent described above include N-methyl-2-pyrrolidone, γ-butyrolactone, dimethoxyimidazolidinone, and 3-methoxy-N,N-dimethylpropaneamide, and, among them, 3-methoxy-N,N-dimethylpropaneamide is preferable.

The unsaturated polyimide precursor may be synthesized by allowing a compound expressed as R—OH together with a dehydration condensation agent to react with a polyamide acid solution. The dehydration condensation agent preferably includes at least one selected from the group consisting of trifluoroacetic anhydride, N,N′-dicyclohexylcarbodiimide (DCC), and 1,3-diisopropylcarbodiimide (DIC).

The compound A contained in the unsaturated polyimide precursor can be obtained by allowing a compound expressed as R—OH to react with a tetracarboxylic dianhydride represented by the following Formula (8) so as to form a diester derivative, thereafter allowing a chlorination agent such as thienyl chloride to react therewith so as to convert the diester derivative to an acid chloride, and then allowing a diamine compound expressed as H₂N—Y—NH₂ to react with the acid chloride.

The compound A contained in the unsaturated polyimide precursor can be obtained by allowing a compound expressed as R—OH to react with a tetracarboxylic dianhydride represented by the following Formula (8) so as to form a diester derivative, and then allowing a diamine compound expressed as H₂N—Y—NH₂ and the diester derivative to react with each other in the presence of a carbodiimide compound.

The compound A contained in the unsaturated polyimide precursor can be obtained by allowing a tetracarboxylic dianhydride represented by the following Formula (8) and a diamine compound expressed as H₂N—Y—NH₂ to react with each other to form a polyamide acid, thereafter converting the polyamide acid into an isoimide in the presence of a dehydration condensation agent such as trifluoroacetic anhydride, and then allowing a compound expressed as R—OH to react therewith. Alternatively, a process may be carried out which includes allowing a compound expressed as R—OH to react with a part of the tetracarboxylic dianhydride in advance, and allowing the resultant partially-esterified tetracarboxylic dianhydride and a diamine compound expressed as H₂N—Y—NH₂ to react with each other.

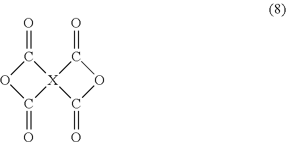

In Formula (8), the specifics of X are the same as those of X in Formula (1), and specific examples and preferable examples thereof are also the same as those of X in Formula (1).

The compound expressed as R—OH used for the synthesis of the aforementioned compound A included in the unsaturated polyimide precursor may be a compound obtained by allowing a hydroxy group to bind to R^{x} of a group represented by Formula (2), or a compound obtained by allowing a hydroxy group to bind to a terminal methylene group of a group represented by Formula (2′), or another compound. Specific examples of the compound expressed as R—OH include methanol, ethanol, n-propanol, isopropanol, n-butanol, 2-hydroxyethyl methacrylate, 2-hydroxyethyl acrylate, 2-hydroxyethyl methacrylate, 2-hydroxypropyl acrylate, 2-hydroxypropyl methacrylate, 2-hydroxybutyl acylate, 2-hydroxybutyl methacrylate, 4-hydroxybutyl acrylate, and 4-hydroxybutyl methacrylate. Among them, 2-hydroxyethyl methacrylate and 2-hydroxyethyl acrylate are preferable.

The molecular weight of the unsaturated polyimide precursor is not particularly limited. For example, the weight average molecular weight of the unsaturated polyimide precursor is preferably from 10,000 to 200,000, and more preferably from 10,000 to 100,000.

Weight average molecular weight can be measured using, for example, the gel permeation chromatography method, and can be obtained through conversion using a standard polystyrene calibration curve.

The photosensitive resin composition according to the present disclosure may further include a dicarboxylic acid, and the unsaturated polyimide precursor contained in the photosensitive resin composition may have a structure obtained by allowing carboxy groups of dicarboxylic acid molecules to react with some of the amino groups present in the unsaturated polyimide precursor. For example, some of the amino groups of the diamine compound molecules may be made to react with carboxy groups of the dicarboxylic acid molecules during the synthesis of the unsaturated polyimide precursor.

The dicarboxylic acid may be a dicarboxylic acid having a (meth)acrylic group, and, for example, may be a dicarboxylic acid represented by the following formula. During the synthesis of the unsaturated polyimide precursor, some of the amino groups of the diamine compound molecules may be made to react with carboxy groups of the dicarboxylic acid molecules, so as to introduce dicarboxylic acid-derived methacrylic groups into the unsaturated polyimide precursor.

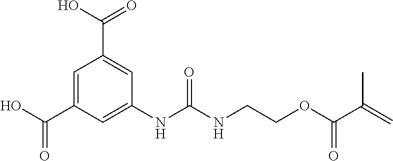 [SMILES: C=C(C)C(=O)OCCNC(=O)Nc1cc(C(=O)O)cc(C(=O)O)c1]

The photosensitive resin composition according to the present disclosure may include a polyimide resin, in addition to the unsaturated polyimide precursor. Using the unsaturated polyimide precursor and a polyimide resin together enables reduction of generation of volatile matter through dehydration cyclization during imide ring formation, and, therefore, has a tendency toward reduction of generation of voids. The polyimide resin as used herein refers to a resin which has an imide skeleton as the entire resin skeleton or a part of the resin skeleton. The polyimide resin is preferably soluble in a solvent contained in the photosensitive resin composition in which the unsaturated polyimide precursor is used.

The polyimide resin is not particularly limited as long as it is a polymer compound that includes plural structural units containing an imide bond. For example, the polyimide resin preferably includes a compound that includes a structural unit represented by the following Formula (X). This tends to enable provision of a semiconductor device that includes an electrically insulating film having high reliability.

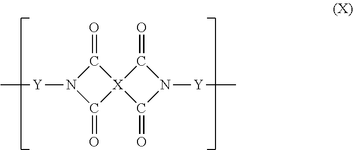

In Formula (X), X represents a tetravalent organic group, and Y represents a divalent organic group. Preferable examples of substituents X and Y in Formula (X) are the same as preferable examples of substituents X and Y in Formula (1).

When the photosensitive resin composition according to the present disclosure includes a polyimide resin, the proportion of the polyimide resin to the total of the unsaturated polyimide precursor and the polyimide resin may be from 15% by mass to 50% by mass, or may be from 10% by mass to 20% by mass.

The photosensitive resin composition according to the present disclosure may include a resin other than the unsaturated polyimide precursor and the polyimide resin. Examples of the other resin include, from the standpoint of heat resistance, a novolac resin, an acrylic resin, a polyethernitrile resin, a polyethersulfone resin, an epoxy resin, a polyethylene terephthalate resin, a polyethylene naphthalate resin, and a polyvinyl chloride resin. Only one other resin may be used, or two or more other resins may be used together.

In the photosensitive resin composition according to the present disclosure, the content ratio of the unsaturated polyimide precursor to the total solids amount is preferably from 50% by mass to 100% by mass, more preferably from 70% by mass to 100% by mass, and may be from 90% by mass to 100% by mass.

The solids refers to the residue left after drying of the photosensitive resin composition at 230° C.

### (Crosslinking Agent)

The photosensitive resin composition includes a crosslinking agent having a vinyl group accompanied by a hydrocarbon group located at an allyl position (a vinyl crosslinking agent). The vinyl crosslinking agent may be used singly, or in combination of two or more thereof.

The hydrocarbon group at an allyl position is, for example, *—CH₂—, *—CH<, or *—C≡, in which * represents the site of bonding to the polymerizable double bond.

The vinyl crosslinking agent may further include a polymerizable unsaturated bond other than the vinyl group accompanied by a hydrocarbon group located at an allyl position, and the other polymerizable unsaturated bond is, for example, a (meth)acryloyl group.

From the standpoint of the balance of an increase in crosslinking density, an increase in exposure sensitivity, and an increase in resolution, the vinyl crosslinking agent preferably includes from 2 to 4 polymerizable unsaturated bonds, and more preferably includes 2 or 3 polymerizable unsaturated bonds.

The molecular weight of the vinyl crosslinking agent is preferably less than or equal to 300, more preferably less than or equal to 200, and still more preferably less than or equal to 150, from the viewpoint of reducing the linear expansion coefficient of a cured film obtained using the vinyl crosslinking agent. The lower limit value of the molecular weight of the vinyl crosslinking agent is not particularly limited, and may be greater than or equal to 90, or may be greater than or equal to 100.

Examples of the vinyl crosslinking agent include the following Formulae (I) to (VII).

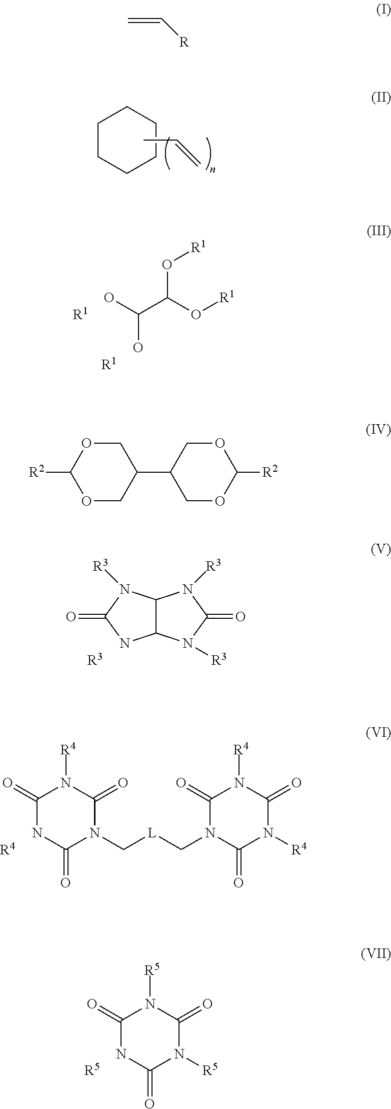

In Formula (I), R represents an organic group, and R may include a (meth)acryloyl group.

In Formula (II), n represents an integer from 1 to 6, preferably an integer from 2 to 4, and more preferably 3.

The positions of the n vinyl groups are not particularly limited. For example, when n is 2, any of the ortho-position, the metha-position, or the para-position may be adopted, and the ortho-position is preferable. In another example, when n is 3, the positions of the n vinyl groups may be any of 1-, 2-, and 3-positions, 1-, 2-, and 4-positions, 1-, 2-, and 5-positions, or 1-, 3-, and 5-positions, and the presence at 1-, 2-, and 4-positions is preferable.

In Formula (III), each R¹ independently represents an allyl group or an organic group other than an allyl group, provided that at least one R¹ represents an allyl group. The number of allyl groups represented by R¹ is from 1 to 4, preferably from 2 to 4, and it is more preferable that all of the four R¹'s represent an allyl group.

Examples of the organic group represented by R¹ include a hydrocarbon group and a (meth)acryloyl group.

In Formula (IV), each R² independently represents a vinyl group or an organic group other than an allyl group, provided that at least one R² represents a vinyl group. The number of vinyl groups represented by R² is 1 or 2, and it is preferable that the two R²'s both represent a vinyl group.

Examples of the organic group represented by R² include a hydrocarbon group and a (meth)acryloyl group.

In Formula (V), each R³ independently represents an allyl group or an organic group other than an allyl group, provided that at least one R³ is an allyl group. The number of allyl groups represented by R³ is from 1 to 4, more preferably from 2 to 4, and it is more preferable that all of the four R^{A}'s represent an allyl group.

Examples of the organic group represented by R³ include a hydrocarbon group and a (meth)acryloyl group.

In Formula (VI), each R⁴ independently represents an allyl group or an organic group other than an allyl group, provided that at least one R⁴ is an allyl group. The number of allyl groups represented by R⁴ is from 1 to 4, more preferably from 2 to 4, and it is preferable that all of the four R^{A}'s represent an allyl group.

Examples of the organic group represented by R⁴ include a hydrocarbon group and a (meth)acryloyl group.

In Formula (VII), each R⁵ independently represents an allyl group or an organic group other than an allyl group, provided that at least one R⁵ is an allyl group. The number of allyl groups represented by R⁵ is from 1 to 3, more preferably from 2 or 3, and still more preferably 2.

Specific examples of the vinyl crosslinking agent include the following compounds.

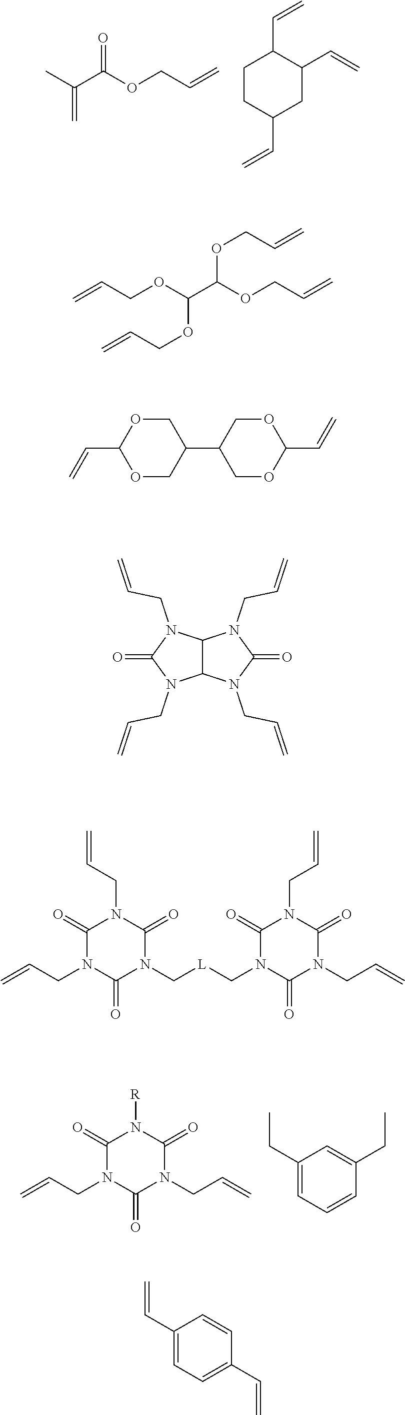

In specific example compounds, L represents a connecting group, and R represents a hydrogen atom or a substituent.

A crosslinking agent other than the vinyl crosslinking agent may additionally be used. From the viewpoint of improving resolution, the proportion of the vinyl crosslinking agent to the total amount of crosslinking agents is preferably 50% by mass or higher, more preferably 70% by mass or higher, still more preferably 95% by mass or higher, particularly preferably 99% by mass or higher, and may be 100% by mass.

The crosslinking agent other than the vinyl crosslinking agent may be a crosslinking agent having a (meth)acryloyl group (hereinafter referred to as a “(meth)acryloyl crosslinking agent”). Examples of the (meth)acryloyl crosslinking agent include an alicyclic crosslinking agent and a linear crosslinking agent.

The aliphatic cyclic skeleton contained in the alicyclic crosslinking agent is not particularly limited, and examples thereof include a tricyclodecane skeleton, a cyclohexane skeleton, a cyclopentane skeleton, a 1,3-adamantane skeleton, a hydrogenated bisphenol A skeleton, a hydrogenated bisphenol F skeleton, a hydrogenated bisphenol S skeleton, and an isobornyl skeleton. Among them, a tricyclodecane skeleton is preferable.

The alicyclic crosslinking agent is preferably a compound represented by the following Formula (3).

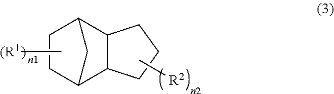

In Formula (3), each of R¹ and R² independently represents an aliphatic hydrocarbon group having from 1 to 4 carbon atoms or a group represented by the following Formula (3-1). Further, n1 represents 0 or 1, n2 represents an integer from 0 to 2, and n1+n2 is 2 or 3. At least two of n1 R¹ and n2 R²(s) are groups represented by the following Formula (3-1).

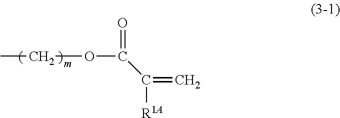

In Formula (3-1), R^{1A} represents a hydrogen atom or a methyl group, and m represents an integer from 1 to 10.

Specific examples of the aliphatic hydrocarbon group having from 1 to 4 carbon atoms represented by R¹ or R² include a methyl group, an ethyl group, an n-propyl group, an isopropyl group, and an n-butyl group.

The compound represented by Formula (3) may be a compound represented by the following Formula (3A) or (3B).

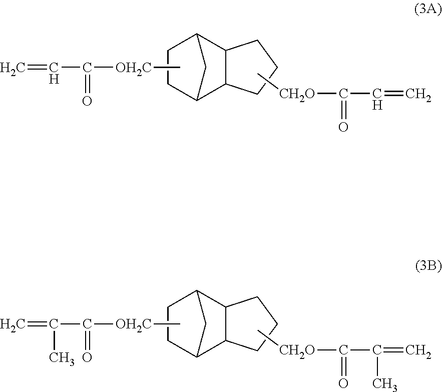

The compound represented by Formula (3A) is available, for example, as A-DCP (tricyclodecane dimethanol diacrylate) manufactured by SHIN-NAKAMURA CHEMICAL Co., Ltd. The compound represented by Formula (3B) is available, for example, as DCP (tricyclodecane dimethanol dimethacrylate) manufactured by SHIN-NAKAMURA CHEMICAL Co., Ltd.

The linear crosslinking agent is preferably a compound represented by the following Formula (4) or Formula (5).

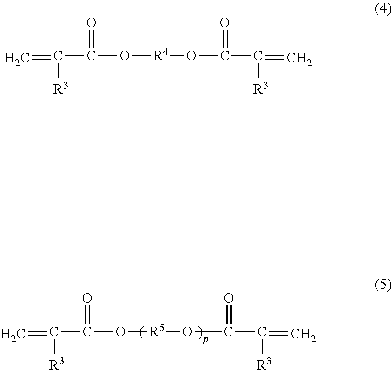

In Formula (4) or (5), each R³ independently represents a hydrogen atom or a methyl group, R⁴ represents a linear alkylene group having from 1 to 8 carbon atoms, R⁵ represents a linear alkylene group having from 1 to 8 carbon atoms, and p represents an integer from 2 to 5. The plural R³'s may be the same or different, and the plural R⁵'s may be the same or different.

R³ in Formula (4) or (5) is preferably a methyl group. Specific examples of the linear alkylene group having from 1 to 8 carbon atoms represented by R⁴ in Formula (4) include a methylene group, an ethylene group, a trimethylene group, a tetramethylene group, a hexamethylene group, and on octamethylene group.

Specific examples of the linear alkylene group having from 1 to 8 carbon atoms represented by R⁵ in Formula (5) include a methylene group, an ethylene group, a trimethylene group, a methylethylene group, a dimethylmethylene group, a tetramethylene group, a hexamethylene group, and on octamethylene group, and methylethylene group and an ethylene group are preferable, and ethylene group is more preferable.

In Formula (5), p is preferably an integer from 3 to 4.

Specific examples of the linear crosslinking agent include diethyleneglycol diacrylate, triethyleneglycol diacrylate, tetraethyleneglycol diacrylate, diethyleneglycol dimethacrylate, triethyleneglycol dimethacrylate, tetraethyleneglycol dimethacrylate, 1,4-butanediol diacrylate, 1,6-hexanediol diacrylate, 1,4-butanediol dimethacrylate, and 1,6-hexanediol dimethacrylate.

Among them, tetraethyleneglycol dimethacrylate is preferable.

From the viewpoint of achieving high resolution, the content of the crosslinking agent is preferably from 1 part by mass to 50 parts by mass, more preferably from 3 parts by mass to 50 parts by mass, and still more preferably from 5 parts by mass to 35 parts by mass, with respect to 100 parts by mass of the unsaturated polyimide precursor.

### (Other Components)

The photosensitive resin composition preferably further includes at least one selected from the group consisting of a photopolymerization initiator, a sensitizer, a ultraviolet absorber, a stabilizer, and a solvent. The photosensitive resin composition may further include an anticorrosion agent, an antioxidant, an imidization promoter, a coupling agent, a thermal polymerization initiator, a surfactant, a leveling agent, unavoidable impurities, or the like.

### [Photopolymerization Initiator]

The photopolymerization initiator is not particularly limited as long as it is a compound capable of generating a radical upon irradiation with an actinic radiation. Examples of the actinic radiation include UV light such as i-line, visible light, and radioactive rays. The photopolymerization initiator may be used singly, or in combination of two or more thereof.

Examples of the photopolymerization initiator include an oxime compound, an acylphosphine oxide compound, and an acyldialkoxymethane compound.

Examples of the photopolymerization initiator include a compound represented by the following Formula (9A), a compound represented by the Formula (9B) presented below, a compound represented by the Formula (10A) presented below, and a compound represented by the Formula (10B) presented below.

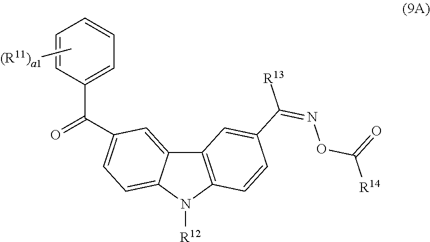

In Formula (9A), R¹¹ represents an alkyl group having from 1 to 12 carbon atoms, and al represents an integer from 0 to 5; R¹² represents a hydrogen atom or an alkyl group having from 1 to 12 carbon atoms; each of R¹³ and R¹⁴ independently represents a hydrogen atom, an alkyl group having from 1 to 12 carbon atoms, a phenyl group, or a tolyl group; when al represents an integer of 2 or greater, R¹¹'s may be the same or different.

R¹¹ represents preferably an alkyl group having from 1 to 4 carbon atoms, and more preferably a methyl group. Preferably, al represents 1. R¹² represents preferably an alkyl group having from 1 to 4 carbon atoms, and more preferably an ethyl group. Each of R¹³ and R¹⁴ independently represents preferably an alkyl group having from 1 to 4 carbon atoms, and more preferably a methyl group.

The compound represented by Formula (9A) is, for example, a compound represented by the following Formula (9A-1), and this compound is available as IRGACURE OXE 02 manufactured by BASF Japan Ltd.

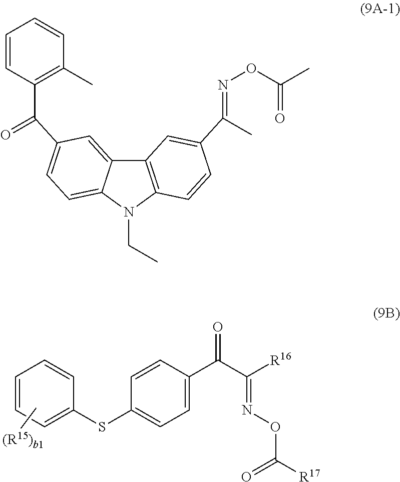

In Formula (9B), R¹⁵ represents —OH, —COOH, —OCH₂OH, —O(CH₂)₂OH, —COOCH₂OH, or —COO(CH₂)₂OH; each of R¹⁶ and R¹⁷ independently represents a hydrogen atom, an alkyl group having from 1 to 12 carbon atoms, a cycloalkyl group having from 4 to 10 carbon atoms, a phenyl group, or a tolyl group; b1 represents an integer from 0 to 5; when b1 represents an integer of 2 or greater, R¹⁵'s may be the same or different.

R¹⁵ represents preferably-O(CH₂)₂OH; and b1 represents preferably 0 or 1. R¹⁶ represents preferably an alkyl group having from 1 to 6 carbon atoms, and more preferably a methyl group or a hexyl group. R¹⁷ represents preferably an alkyl group having from 1 to 6 carbon atoms or a phenyl group, and more preferably a methyl group or a phenyl group.

The compound represented by Formula (9B) is, for example, a compound represented by the following Formula (9B-1), and this compound is available as IRGACURE OXE 01 manufactured by BASF Japan Ltd. Another example is a compound represented by the following Formula (9B-2), and this compound is available as NCI-930 manufactured by ADEKA Corporation.

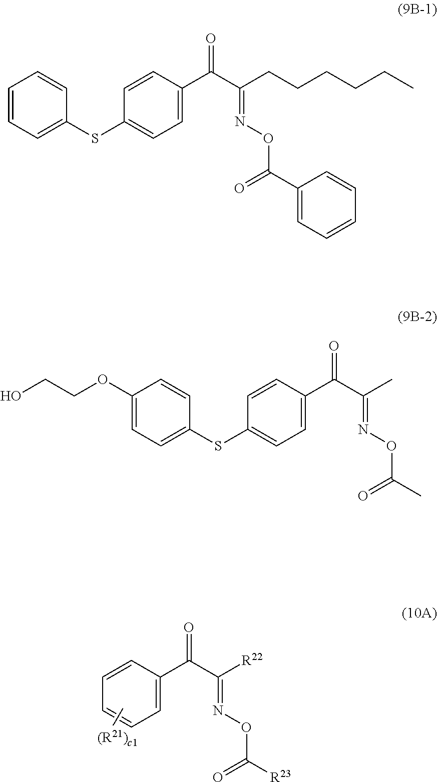

In Formula (10A), R²¹ represents an alkyl group having from 1 to 12 carbon atoms; each of R²² and R²³ independently represents a hydrogen atom, an alkyl group having from 1 to 12 carbon atoms (preferably from 1 to 4 carbon atoms), an alkoxy group having from 1 to 12 carbon atoms (preferably from 1 to 4 carbon atoms), a cycloalkyl group having from 4 to 10 carbon atoms, a phenyl group, or a tolyl group; c1 represents an integer from 0 to 5; when c1 represents an integer of 2 or greater, R²¹'s may be the same or different.

Preferably, c1 represents 0. R²² represents preferably an alkyl group having from 1 to 4 carbon atoms, and more preferably a methyl group. R²³ represents preferably an alkoxy group having from 1 to 12 carbon atoms, more preferably an alkoxy group having from 1 to 4 carbon atoms, and still more preferably a methoxy group or an ethoxy group.

The compound represented by Formula (10A) is, for example, a compound represented by the following Formula (10A-1), and this compound is available as G-1820 (PDO) manufactured by Lambson Ltd.

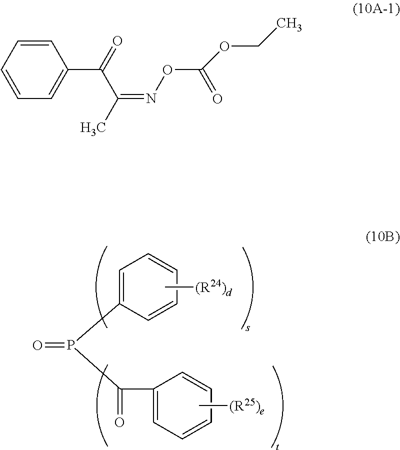

In Formula (10B), each of R²⁴ and R²⁵ independently represents an alkyl group having from 1 to 12 carbon atoms (preferably from 1 to 4 carbon atoms); each of d and e independently represents an integer from 0 to 5; each of s and t independently represents an integer from 0 to 3, provided that the sum of s and t is 3; when d represents an integer of 2 or greater, R²⁴'s may be the same or different; when e represents an integer of 2 or greater, R²⁵'s may be the same or different; when s represents an integer of 2 or greater, each group shown in the parentheses may be same or different; and when t represents an integer of 2 or greater, each group shown in the parentheses may be same or different.

Preferably, d represents 0. Each R²⁵ independently represents preferably an alkyl group having from 1 to 4 carbon atoms, and more preferably a methyl group. Preferably, e represents an integer from 2 to 4, and more preferably 3. The combination of s and t (s, t) is preferably (1, 2) or (2, 1).

The compound represented by Formula (10B) is, for example, a compound represented by the following Formula (10B-1), and this compound is available as IRGACURE TPO manufactured by BASF Japan Ltd. Another examples is a compound represented by the following Formula (10B-2), and this compound is available as IRGACURE 819 manufactured by BASF Japan Ltd.

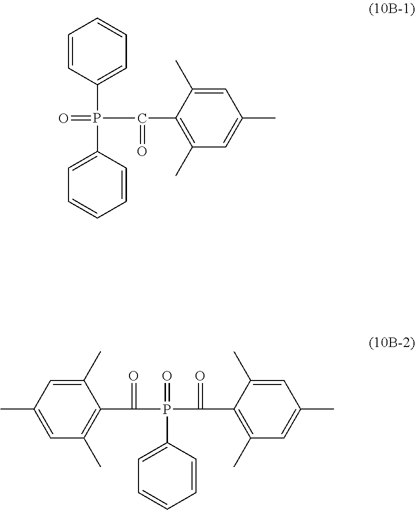

Among the photopolymerization initiators exemplified above, a compound represented by Formula (9B) or a compound represented by Formula (9A-1) is preferably used in combination with the vinyl crosslinking agent, from the standpoint of resolution.

The content of the photopolymerization initiator is preferably from 0.1 parts by mass to 20 parts by mass, more preferably from 0.1 parts by mass to 10 parts by mass, and still more preferably from 0.1 parts by mass to 6 parts by mass, with respect to 100 parts by mass of the unsaturated polyimide precursor.

### (Solvent)

Examples of the solvent include an ester solvent, an ether solvent, a ketone solvent, a hydrocarbon solvent, an aromatic hydrocarbon solvent, and a sulfoxide solvent. The solvent may be used singly, or in combination of two or more thereof.

Examples of the ester solvent include ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, γ-butyrolactone, ε-caprolactone, δ-valerolactone, an alkyl alkoxyacetate such as a methyl alkoxyacetate, an ethyl alkoxyacetate, or a butyl alkoxyacetate (for example, methyl methoxyacetate, ethyl methoxyacetate, butyl methoxyacetate, methyl ethoxyacetate, or ethyl ethoxyacetate), an alkyl ester of 3-alkoxypropionic acid such as a methyl 3-alkoxypropionate or ethyl 3-alkoxypropionate (for example, methyl 3-methoxypropionate, ethyl 3-methoxypropionate, methyl 3-ethoxypropionate, or ethyl 3-ethoxypropionate), an alkyl ester of 2-alkoxypropionic acid such as a methyl 2-alkoxypropionate, an ethyl 2-alkoxypropionate, or a propyl 2-alkoxypropionate, (for example, methyl 2-methoxypropionate, ethyl 2-methoxypropionate, propyl 2-methoxypropionate, methyl 2-ethoxypropionate, or ethyl 2-ethoxypropionate), a methyl 2-alkoxy-2-methylpropionate such as methyl 2-methoxy-2-methylpropionate, an ethyl 2-alkoxy-2-methylpropionate such as ethyl 2-ethoxy-2-methylpropionate, methyl pyruvate, ethyl pyruvate, propyl pyruvate, methyl acetoacetate, ethyl acetoacetate, methyl 2-oxybutanoate, and ethyl 2-oxobutanoate.

Examples of the ether solvent include diethyleneglycol dimethyl ether, tetrahydrofuran, ethyleneglycol monomethyl ether, ethyleneglycol monoethyl ether, metylcellosolve acetate, ethylcellosolve acetate, diethyleneglycol monomethyl ether, diethyleneglycol monoethyl ether, diethyleneglycol monobutyl ether, propyleneglycol monomethyl ether, propyleneglycol monomethyl ether acetate, propyleneglycol monoethyl ether acetate, and propyleneglycol monopropyl ether acetate.

Examples of the ketone solvent include methyl ethyl ketone, cyclohexanone, cyclopentanone, 2-heptanone, 3-heptanone, and N-methyl-2-pyrrolidone (NMP).

Examples of the hydrocarbon solvent include limonene.

Examples of the aromatic hydrocarbon solvent include toluene, xylene, and anisole.

Examples of the sulfoxide solvent include dimethyl sulfoxide.

Among them, N-methyl-2-pyrrolidone, γ-butyrolactone, ethyl lactate, propyleneglycol monomethyl ether acetate, N,N-dimethylformamide, and N,N-dimethylacetamide are preferable from the viewpoint that these solvents have excellent properties in terms of dissolution of respective components and coatability at the time of forming a photosensitive resin film.

A compound represented by the following Formula (11) is also usable as a solvent.

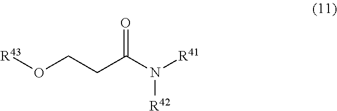

In Formula (11), each of R⁴¹ to R⁴³ independently represents an alkyl having from 1 to 10 carbon atoms.

In Formula (11), the number of carbon atoms of the alkyl group represented by any of R⁴¹ to R⁴³ is preferably from 1 to 3, and more preferably 1 or 3.

Specific examples of the alkyl group having from 1 to 10 carbon atoms represented by any of R⁴¹ to R⁴³ include a methyl group, an ethyl group, an n-propyl group, an isopropyl group, an n-butyl group, a t-butyl group, a pentyl group, a hexyl group, a heptyl group, and an octyl group.

The compound represented by Formula (11) is preferably 3-methoxy-N,N-dimethylpropaneamide (for example, product name KJCMPA-100 manufactured by KJ Chemicals Corporation).

The content of the solvent may be adjusted, as appropriate, in accordance with, for example, the viscosity of the photosensitive resin composition. The content of the solvent is, for example, greater than or equal to 50 parts by mass, or greater than or equal to 80 parts by mass, or greater than or equal to 100 parts by mass, with respect to 100 parts by mass of the unsaturated polyimide precursor. From the viewpoint of reducing the drying energy required for forming a coating film, inclusion of an excessive amount of solvent is unnecessary. The content of the solvent is, for example, less than or equal to 300 parts by mass, or less than or equal to 200 parts by mass, with respect to 100 parts by mass of the unsaturated polyimide precursor.

### [Sensitizing Agent]

The photosensitive resin composition according to the present disclosure may include a sensitizing agent. Inclusion of a sensitizing agent in the photosensitive resin composition enables achievement of both of maintenance of residual film rate and excellent resolution at a wide range of exposure amount.

Examples of the sensitizing agent include Michiller's ketone, benzoin, 2-methylbenzoin, benzoin methyl ether, benzoin ethyl ethe, benzoin isopropyl ether, benzoin butyl ether, 2-t-butylanthraquinone, 1,2-benzo-9,10-anthraquinone, anthraquinone, methylanthraquinone, 4,4′-bis(diethylamino)benzophenone, acetophenone, benzophenone, thioxanthone, 1,5-acenaphthene, 2,2-dimethoxy-2-phenylacetophenone, 1-hydroxycylohexyl phenyl ketone, 2-methyl-[4-(methylthio)phenyl]-2-morpholino-1-propanone, diacetylbenzyl, benzil dimethyl ketal, benzil diethyl ketal, diphenyl disulfide, anthracene, phenanthrene quinone, riboflavine tetrabutyrate, acridine orange, erythrosine, phenanthrene quinone, 2-isopropyl thioxanthone, 2,6-bis(p-diethylaminobenzylidene)-4-methyl-4-azacyclohexanone, 6-bis(p-dimethylaminobenzylidene)-cyclopentanone, 2,6-bis(p-diethylaminobenzylidene)-4-phenylcyclohexanone, aminostyryl ketone, a 3-ketocoumarin compound, a bis-coumarin compound, an N-phenylglycine, and 3,3′,4,4′-tetra(t-butylperoxycarbonyl)benzophenone.

The sensitizer may be used singly, or in combination of two or more thereof.

When the photosensitive resin composition according to the present disclosure includes a sensitizer, the addition amount of the sensitizer is not particularly limited, and is preferably from 0.1 parts by mass to 1.0 parts by mass, and more preferably from 0.2 parts by mass to 0.8 parts by mass, with respect to 100 parts by mass of the unsaturated polyimide precursor.

### [Stabilizer]

The photosensitive resin composition according to the present disclosure may include a stabilizer. Inclusion of a stabilizer in the photosensitive resin composition makes it possible to obtain an excellent stability when the photosensitive resin composition is left to stand.

Examples of the stabilizer include p-methoxyphenol, diphenyl-p-benzoquinone, benzoquinone, hydroquinone, pyrogallol, phenanthiazine, resorcinol, ortho-dinitrobenzene, para-dinitrobenzene, meta-dinitrobenzene, phenanthraquinone, N-phenyl-2-naphthylamine, cupferron, 2,5-toluquinone, tanninic acid, parabenzylaminophenol, a nitrosoamine, an azo compound, a hindered amine-containing compound, and a hindered phenol-containing compound.

The stabilizer may be used singly, or in combination of two or more thereof. Combined use of two or more stabilizers tends to facilitate control of photosensitive properties based on a difference in reactivities therebetween. The hindered phenol-containing compound may have both of stabilizer function and the after-mentioned antioxidant function, or may have only one of these functions.

Examples of the stabilizer include 2,6-di-t-butyl-4-methylphenol, 2,5-di-t-butyl-hydroquinone, octadecyl-3-(3,5-di-t-butyl-4-hydroxyphenyl) propionate, isooctyl-3-(3,5-di-t-butyl-4-hydroxyphenyl) propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethyleneglycol-bis[3-(3-t-butyl-5-methyl-4-hydroxyphenyl) propionate], 1,6-hexanediol-bis[3-(3,5-di-t-butyl-4-hydroxyphenyl) propionate], 2,2-thio-diethylenebis[3-(3,5-di-t-butyl-4-hydroxyphenyl) propionate], N,N′-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaeythrityl-tetrakis[3-(3,5-di-t-butyl-4-hydroxyphenyl) propionate], tris-(3,5-di-t-butyl-4-hydroxybenzyl)-isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, 1,3,5-tris(4-t-butyl-5-ethyl-3-hydroxy-2-methylbenzyl)-1,3,5-triazine-2,4,6-(1H,3H,5H)-trione, N,N′-hexane-1,6-diyl bis[3-(3,5-di-tert-butyl-4-hydroxyphenyl) propionamide], 2,2,6,6-tetramethylpyperidine 1-oxyl, 4-hydroxy-2,2,6,6-tetramethylpyperidine 1-oxyl, and 1,4,4-trimethyl-2,3-diazabicyclo[3.2.2]nona-2-ene-2,3-dioxide.

When the photosensitive resin composition according to the present disclosure includes a stabilizer, the content of the stabilizer is preferably from 0.05 parts by mass to 1.0 parts by mass, and more preferably from 0.1 parts by mass to 0.8 parts by mass, with respect to 100 parts by mass of the unsaturated polyimide precursor.

### [Antioxidant]

The photosensitive resin composition according to the present disclosure may include an antioxidant, considering that trapping of oxygen radicals and peroxide radicals generated by, for example, storage at high temperatures or reflow processing enables a decrease in adhesion properties to be curbed. When the photosensitive resin composition according to the present disclosure includes an antioxidant, oxidization of electrodes at the time of electric insulation reliability testing can be reduced.

Specific examples of the antioxidant include the compounds exemplified above as hindered phenol-containing compounds, N,N′-bis[2-[2-(3,5-di-tert-butyl-4-hydroxyphenyl)ethylcarbonyloxy]ethyl]oxamide, N,N′-bis-3-(3,5-di-tert-butyl-4-hydroxyphenyl), propionyl hexamethylene diamine, 1,3,5-tris(3-hydroxy-4-tert-butyl-2,6-dimethylbenzyl)-1,3,5-triazine-2,4,6(1H,3H,5H)-trione, and 1,3,5-tris(4-t-butyl-3-hydroxy-2,6-dimethylbenzyl) isocyanuric acid.

The antioxidant may be used singly, or in combination of two or more thereof.

When the photosensitive resin composition according to the present disclosure includes an antioxidant, the content of the antioxidant is preferably from 0.1 parts by mass to 20 parts by mass, more preferably from 0.1 parts by mass to 10 parts by mass, and still more preferably from 0.1 parts by mass to 5 parts by mass, with respect to 100 parts by mass of the unsaturated polyimide precursor.

### [Imidization Promoter]

The resin composition according to the present disclosure may include an imidization promoter from the viewpoint of promoting an imidization reaction.

Specific examples of the imidization promoter include N-phenyldiethanolamine, 2-(methylphenylamino)ethanol, 2-(ethylanilino)ethanol, N-methylaniline, N-ethylaniline, N,N′-dimethylaniline, N-phenylethanolamine, 4-phenylmorpholine, 2,2′-(4-methylphenylimino)diethanol, 4-aminobenzamide, 2-aminobenzamide, nicotineamide, 4-amino-N-methylbenzamide, 4-aminoacetoanilide, and 4-aminoacetophenone. Among them, N-methylaniline, N-ethylaniline, N,N′-dimethylaniline, N-phenylethanolamine, 4-phenylmorpholine, 2,2′-(4-methylphenylimino)diethanol, and the like are preferable. The imidization promoter may be used singly, or in combination of two or more thereof.

When the resin composition according to the present disclosure includes an imidization promoter, the content of the imidization promoter is preferably from 0.1 parts by mass to 20 parts by mass with respect to 100 parts by mass of the unsaturated polyimide precursor. From the standpoint of storage stability, the content of the imidization promoter is more preferably from 0.3 parts by mass to 15 parts by mass, and still more preferably from 0.5 parts by mass to 10 parts by mass, with respect to 100 parts by mass of the unsaturated polyimide precursor.

### [Coupling Agent]

The coupling agent is not particularly limited, and examples thereof include: silane coupling agents such as 3-aminopropyl trimethoxysilane, N-(2-aminoethyl)-3-aminopropylmethyl dimethoxysilane, 3-glycidoxypropyl methyl dimethoxysilane, 3-mercaptopropyl methyl dimethoxysilane, 3-methacryloxypropyl dimethoxy methylsilane, 3-methacryloxypropyl trimethoxysilane, dimethoxy(methyl) (3-piperidinopropyl) silane, diethoxy(3-glycidoxypropyl)(methyl) silane, N-(3-diethoxymethylsilylpropyl) succinimide, N-[3-(triethoxysilyl)propyl]phthalamic acid, benzophenone-3,3′-bis(N-[3-triethoxysilyl]propylamido)-4,4′-dicarboxylic acid, benzene-1,4-bis(N-[3-triethoxysilyl]propylamido)-2,5-dicarboxylic acid, 3-(triethoxysilyl) propyl succinic anhydride, N-phenylaminopropyl trimethoxysilane, N,N′-bis(2-hydroxyethyl)-3-aminopropyl triethoxysilane, and 3-ureidopropyl triethoxysilane; and aluminum-containing adhesion aids such as aluminum tris(ethyl acetoacetate), aluminum tris(acetylacetonate), and aluminum ethyl acetoacetate diisopropylate.

The coupling agent may be used singly, or in combination of two or more thereof.

When the photosensitive resin composition according to the present disclosure includes a coupling agent, the content of the coupling agent is preferably from 0.1 parts by mass to 20 parts by mass, more preferably from 1 part by mass to 10 parts by mass, and still more preferably from 2 parts by mass to 10 parts by mass, with respect to 100 parts by mass of the unsaturated polyimide precursor.

### [Anticorrosion Agent]

The resin composition according to the present disclosure may include an anticorrosion agent, from the viewpoints of reducing corrosion of copper or copper alloys and preventing discoloration.

The anticorrosion agent is not particularly limited, and examples thereof include an azole compound and a purine derivative.

The anticorrosion agent may be used singly, or in combination of two or more thereof.

Specific examples of the azole compound include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, 2-(2′-hydroxy-5′-t-octylphenyl)benzotriazole, hydroxyphenyl benzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, and 1-methyl-1H-tetrazole.

Specific examples of the purine derivative include purine, adenine, guanine, hypoxanthine, xanthine, theobromine, caffeine, uric acid, isoguanine, 2,6-diaminopurine, 9-methyladenine, 2-hydroxyadenine, 2-methyladenine, 1-methyladenine, N-methyladenine, N,N-dimethyladenine, 2-fluoroadenine, 9-(2-hydroxyethyl) adenine, guanine oxime, N-(2-hydroxyethyl) adenine, 8-aminoadenine, 6-amino-8-phenyl-9H-purine, 1-ethyladenine, 6-ethylaminopurine, 1-benzyladenine, N-methylguanine, 7-(2-hydroxyethyl) guanine, N-(3-chlorophenyl) guanine, N-(3-ethylphenyl) guanine, 2-azaadenine, 5-azaadenine, 8-azaadenine, 8-azaguanine, 8-azapurine, 8-azaxanthine, 8-azahypoxanthine, and derivatives thereof.

When the photosensitive resin composition according to the present disclosure includes an anticorrosion agent, the content of the anticorrosion agent is preferably from 0.01 parts by mass to 10 parts by mass, more preferably from 0.1 parts by mass to 5 parts by mass, and still more preferably from 0.5 parts by mass to 3 parts by mass, with respect to 100 parts by mass of the unsaturated polyimide precursor.

### [UV Absorber]

The photosensitive resin composition according to the present disclosure may include a UV absorber, from the viewpoint of reducing crosslinking of unexposed portions due to diffuse reflection during light exposure.

The UV absorber preferably has an absorbance of 0.05 or more, more preferably 0.1 or more, at 365 nm at a concentration of 10 mg/L. Examples of the UV absorber include a benzotriazole-containing compound, a salicylic ester-containing compound, a benzophenone-containing compound, a diphenylacrylate-containing compound, a cyanoacrylate-containing compound, a diphenylcyanoacrylate-containing compound, a benzothiazole-containing compound, an azobenzene-containing compound, a polyphenol-containing compound, and a nickel complex salt-containing compound. The UV absorber may be used singly, or in combination of two or more thereof.

Examples of the benzotriazole-containing compound include 2-(2-hydroxy-5-methylphenyl)-2H-benzotriazole, 2-(3-tert-butyl-2-hydroxy-5-methylphenyl)-5-chloro-2H-benzotriazole, 2-(3,5-di-tert-pentyl-2-hydroxyphenyl)-2H-benzotriazole, 2-(2H-benzotriazole-2-yl)-4-methyl-6-(3,4,5,6-tetrahydrophthalimidylmethyl)phenol, 2-(2-hydroxy-4-octyloxyphenyl)-2H-benzotriazole, 2-(2-hydroxy-5-tert-octylphenyl)-2H-benzotriazole, 2-(2H-benzotriazole-2-yl)-4-(1,1,3,3-tetramethylbutyl)phenol, 2-(2H-benzotriazole-2-yl)-4,6-bis(1-methyl-1-phenylethyl)phenol, and 2-(2H-benzotriazole-2-yl)-p-cresol.

Examples of the salicylic ester-containing compound include phenyl salicylate and 4-tert-butylphenyl salicylate.

Examples of the benzophenone-containing compound include 2,4-dihydroxybenzophenone, 2-hydroxy-4-methoxybenzophenone, 2-hydroxy-4-n-octyloxybenzophenone, 4-n-dodecyloxy-2-hydroxybenzophenone, 2-hydroxy-4-methoxybenzophenone-5-sulfonic acid trihydrate, 2,2′,4,4′-tetrahydroxybenzophenone, and 2,2′-dihydroxy-4,4′-dimethoxybenzophenone.

Examples of the diphenyl acrylate-containing compound include ethyl 2-cyano-3,3-diphenylacrylate.

Examples of the diphenylcyanoacrylate-containing compound include 2′-ethylhexyl 2-cyano-3,3-diphenylacrylate.

Examples of the azobenzene-containing compound include 4-[ethyl(2-hydroxyethyl)amino]-4′-nitroazobenzene.

Examples of the polyphenol-containing compound include pyrogallol, phlororoglucinol, catechin, epicatechin, gallocatechin, catechin gallate, gallocatechin gallate, epicatechin gallate, epigallocatechin gallate, epigallocatechin, rutin, quercetin, quercetagin, quercetagetin, gossypetin, pelargonidin, cyanidin, aurantinidin, luteolinidin, peonidin, rosinidin, (1E,6E)-1,7-bis(4-hydroxy-3-methoxyphenyl)-1,6-hetadiene-3,5-dione, and 1,7-bis(4-hydroxyphenyl)-1,6-heptadiene-3,5-dione.

Examples of the polyphenol-containing compound include [2,2′-thiobis(4-tert-octylphenolate)]-2-ethylhexylamine nickel (II).

Among the foregoing, use of at least one UV absorber selected from the group consisting of a benzotriazole-containing compound, a benzophenone-containing compound, an azobenzene-containing compound, and a polyphenol-containing compound is preferable.

From the standpoint of resolution, use of at least one UV absorber selected from the group consisting of 2-(2H-benzotriazole-2-yl)-4-(1,1,3,3-tetramethylbutyl)phenol, 2-(2H-benzotriazole-2-yl)-4,6-bis(1-methyl-1-phenylethyl)phenol, 2-(2H-benzotriazole-2-yl)-p-cresol, 2,2′,4,4′-tetrahydroxybenzophenone, 2,2′-dihydroxy-4,4′dimethoxybenzophenone, 4-[ethyl(2-hydroxyethyl)amino]-4′-nitroazobenzene, (1E,6E)-1,7-bis(4-hydroxy-3-methoxyphenyl)-1,6-heptadiene-3,5-dione (curcumin), and 1,7-bis(4-hydroxyphenyl)-1,6-heptadiene-3,5-dione is more preferable.

When the photosensitive resin composition according to the present disclosure includes a UV absorber, the content of the UV absorber is preferably greater than or equal to 0.05 parts by mass, more preferably greater than or equal to 0.1 parts by mass, and still more preferably greater than or equal to 0.2 parts by mass, with respect to 100 parts by mass of the unsaturated polyimide precursor, from the standpoint of resolution.

From the viewpoint of avoiding insufficient photocuring inside the coating film, the content of the UV absorber is preferably less than or equal to 5 parts by mass, more preferably less than or equal to 3 parts by mass, and still more preferably less than or equal to 2 parts by mass.

### [Surfactant and Leveling Agent]

Examples of the surfactant or the leveling agent include polyoxyethylene lauryl ether, polyoxyethylene stearyl ether, polyoxyethylene oleyl ether, and polyoxyethylene octyl phenol ether, and commercially available products of the surfactant or the leveling agent include product names MEGAFACE (registered trademark) F171, F173, and R-08 (manufactured by DIC Corporation), product names FLUORAD FC430 and FC431 (manufactured by Sumitomo 3M Limited), and product names Organosiloxane Polymer KP341, KBM303, and KBM803 (manufactured by Shin-Etsu Chemical Co., Ltd.)

Only one surfactant or leveling agent may be used, or two or more surfactants or leveling agents may be used in combination.

When the photosensitive resin composition according to the present disclosure includes at least one of a surfactant or a leveling agent, the total content of surfactants and leveling agents is preferably from 0.01 parts by mass to 10 parts by mass, more preferably from 0.05 parts by mass to 5 parts by mass, and still more preferably from 0.05 parts by mass to 3 parts by mass, with respect to 100 parts by mass of the unsaturated polyimide precursor.

### [Thermal Polymerization Initiator]

The photosensitive resin composition according to the present disclosure may further include a thermal polymerization initiator, from the viewpoint of promoting the polymerization reaction.

The thermal polymerization initiator is preferably a compound that does not decompose when heated (dried) for removing solvent upon film formation, and that decomposes when heated during curing and generates a radical, thereby promoting a polymerization reaction between polymerizable monomer molecules or a polymerization reaction between the unsaturated polyimide precursor and a polymerizable monomer.

The thermal polymerization initiator is preferably a compound having a decomposition point of from 110° C. to 200° C. From the viewpoint of promoting the polymerization reaction at lower temperatures, the thermal polymerization initiator is more preferably a compound having a decomposition point of from 110° C. to 175° C.

Specific examples of the thermal polymerization initiator include: ketone peroxides such as methyl ethyl ketone peroxide; peroxyketals such as 1,1-di(t-hexylperoxy)-3,3,5-trimethylcyclohexane, 1,1-di(t-hexylperoxy)cyclohexane, and 1,1-di(t-butylperoxy)cyclohexane; hydroperoxides such as 1,1,3,3-tetramethylbutyl hydroperoxide, cumene hydroperoxide, and p-menthane hydroperoxide; dialkyl peroxides such as dicumyl peroxide and di-t-butyl peroxide; diacyl peroxides such as dilauroyl peroxide and dibenzoyl peroxide; peroxy dicarbonates such as di(4-t-butylcylohexyl)peroxydicarbonate and di(2-ethylhexyl)peroxydicarbonate; peroxy esters such as t-butyl peroxy-2-ethylhexanoate, t-hexyl peroxyisopropylmonocarbonate, t-butyl peroxybenzoate, and 1,1,3,3-tetramethylbutyl peroxy-2-ethylhexanoate; and bis(1-phenyl-1-methylethyl) peroxide.

Examples of commercially available products include product names PERCUMYL D, PERCUMYL P, and PERCUMYL H (manufactured by NOF Corporation).

When the photosensitive resin composition according to the present disclosure includes a thermal polymerization initiator, the content of the thermal polymerization initiator with respect to 100 parts by mass of the unsaturated polyimide precursor is preferably from 0.1 parts by mass to 20 parts by mass, and, for ensuring an excellent flux resistance, more preferably from 0.2 parts by mass to 20 parts by mass, and, from the viewpoint of curbing a decrease in solubility due to decomposition at the time of drying, still more preferably from 0.3 parts by mass to 10 parts by mass.

### [Content of Main Components]

In the photosensitive resin composition according to the present disclosure, the total amount of the unsaturated polyimide precursor, the crosslinking agent, the photopolymerization initiator, and the solvent may be 80% by mass or more, or may be 90% by mass or more, or may be 95% by mass or more.

In the photosensitive resin composition according to the present disclosure, the total amount of the unsaturated polyimide precursor, the crosslinking agent, the photopolymerization initiator, the solvent, the stabilizer, the sensitizing agent, the UV absorber, the imidization promoter, the anticorrosion agent, the antioxidant, and the coupling agent may be 80% by mass or more, or may be 90% by mass or more, or may be 95% by mass or more, or may be 97% by mass or more, or may be 98% by mass or more, or may be 99% by mass or more.

### <Curing Agent>

The cured product according to the present disclosure can be obtained by curing the photosensitive resin composition according to the present disclosure. The cured product according to the present disclosure can suitably be used as a patterned cured product. The average thickness of the cured product is preferably from 5 μm to 20 μm.

### <Method of Producing Cured Product, and Electronic Component>

A method of producing a patterned cured product according to the present disclosure includes:
a step of applying the photosensitive resin composition according to the present disclosure to a substrate, and drying the photosensitive resin composition, thereby forming a photosensitive resin film;
a step of patternwise exposing the photosensitive resin film, thereby obtaining a resin film;
a step of developing the resin film after patternwise exposure with a developer, thereby obtaining a patterned resin film, and
a step of heating the patterned resin film.

Through this method, a patterned cured product can be obtained.

Examples of the substrate include a glass substrate, a semiconductor substrate such as a Si substrate (silicon wafer), a metal oxide electrically insulating substrate such as a TiO₂ substrate or a SiO₂ substrate, a silicon nitride substrate, a copper substrate, and a copper alloy substrate.

The method used for applying the photosensitive resin composition according to the present disclosure is not particularly limited, and the application can be performed using a spinner or the like.

The drying can be performed using, for example, a hot plate or an oven. The drying temperature is preferably from 90° C. to 150° C. The drying temperature is more preferably from 90° C. to 120° C., from the viewpoint of ensuring dissolution contrast.

The drying time is preferably from 30 seconds to 5 minutes. Drying may be performed twice or more times.

As a result of the drying, a photosensitive resin film that is the photosensitive resin composition according to the present disclosure formed into a film can be obtained.

The average thickness of the photosensitive resin film is preferably from 1 μm to 100 μm, more preferably from 2 μm to 50 μm, and still more preferably from 3 μm to 20 μm.

The patternwise exposure includes, for example, exposure to light in a desired pattern through a photomask. Examples of the actinic radiation used for the exposure include an ultraviolet light such as i-line, visible light, and radioactive rays, and the actinic radiation is preferably i-line. Examples of the exposure device to be used include a parallel light exposure device, an aligner, a projection exposure device, a stepper, and a scanner exposure device.

After the development, a patternwise formed resin film (patterned resin film) can be obtained. In general, in a case in which a negative-working photosensitive resin composition is used, unexposed portions are removed using a developer.

The developer to be used may be a good solvent for the photosensitive resin film alone, or an appropriate mixture of a good solvent and a poor solvent.

Examples of the good solvent include N-methyl-2-pyrrolidone, N-acetyl-2-pyrrolidone, N,N-dimethylacetamide, N,N-dimethylformamide, dimethylsulfoxide, γ-butyrolactone, α-acetyl-γ-butyrolactone, cyclopentanone, and cyclohexanone.

Examples of the poor solvent include toluene, xylene, methanol, ethanol, isopropanol, propyleneglycol monomethyl ether acetate, propylenegycol monomethyl ether, and water.

A surfactant may be added to the developer. The addition amount of the surfactant is preferably from 0.01 parts by mass to 10 parts by mass, and more preferably from 0.1 parts by mass to 5 parts by mass, with respect to 100 parts by mass of the developer.

The development time can be set to, for example, a length of time that is twice the time it takes for the immersed photosensitive resin film to completely dissolve. The development time varies with the unsaturated polyimide precursor to be used. Although the development time varies with the unsaturated polyimide precursor species to be used, the development time is preferably from 10 seconds to 15 minutes, and more preferably from 10 seconds to 5 minutes. From the standpoint of productivity, the development time is still more preferably from 20 seconds to 5 minutes.

After the development, washing with rinse liquid may be performed. The rinse liquid is, for example, one of distilled water, methanol, ethanol, isopropanol, toluene, xylene, propyleneglycol monomethyl ether acetate, propyleneglycol monomethyl ether, or the like, or an appropriate mixture of two or more thereof. Alternatively, different combinations of such liquids may be used in stages.

After the patterned resin film is heated, a patterned cured product can be obtained. The unsaturated polyimide precursor undergoes a dehydration ring-closing reaction during the heating step, and is transformed into a corresponding polyimide resin.

The heating temperature is preferably lower than or equal to 250° C., more preferably from 120° C. to 250° C., and still more preferably from 160° C. to 200° C. A heating temperature within the foregoing ranges enables damage to the substrate or device to be reduced, enables high yield production of the device, and enables an energy saving process to be realized.

The heating time is preferably less than or equal to 5 hours, and more preferably from 30 minutes to 3 hours. A heating time with the foregoing ranges enables the crosslinking reaction or dehydration ring-closing reaction to proceed sufficiently. The surrounding atmosphere for the heating may be the atmospheric air or an inactive atmosphere such as nitrogen. From the viewpoint that oxidation of the patterned resin film can be prevented, a nitrogen atmosphere is preferable.

Examples of the device used for the heating include a quartz tube furnace, a hot plate, a rapid thermal anneal, a vertical diffusion furnace, an infrared curing furnace, an electron beam curing furnace, and a microwave curing furnace.

The cured product according to the present disclosure can be used as an interlayer insulating film, a cover-coat layer, or a surface protective film. The cured product according to the present disclosure can also be used as a passivation film, a buffer coat film, or the like.

Electronic components, such as semiconductor devices, multilayer circuit boards, various electronic devices, and stacked devices (for example, multi-die fan-out wafer-level package), that have high reliability can be produced using at least one selected from the group consisting of the passivation film, the buffer coat film, the interlayer insulating film, the cover-coat layer, or the surface protective film described above.

One example of a process for producing a semiconductor device as an electronic component according to the present disclosure is described below with reference to a drawing.

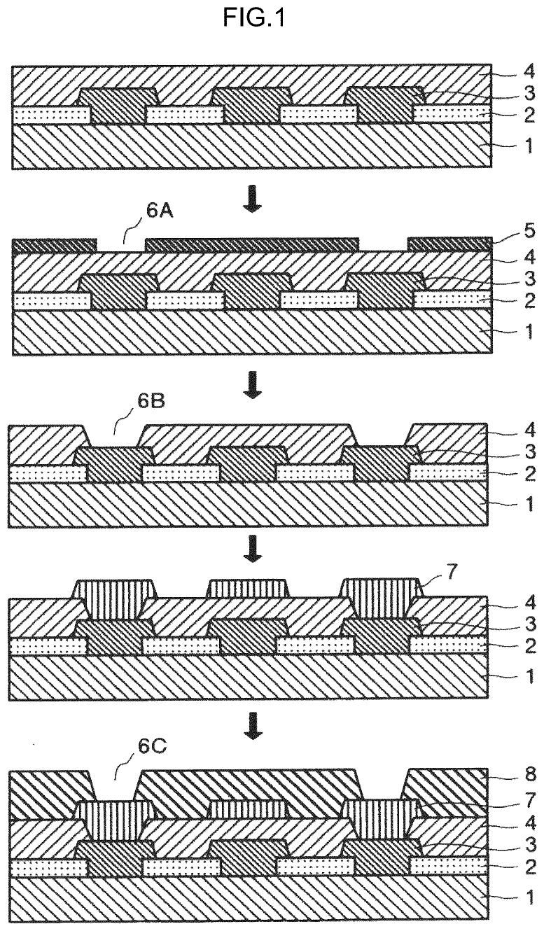

FIG. 1 is a process diagram for producing a semiconductor device having a multilayer wiring structure as an electronic component according to one embodiment of the present disclosure. In FIG. 1, a semiconductor 1, such as a Si substrate, having a circuit element is coated with a protective film 2, such as a silicon oxide film, except for predetermined portions of the circuit element, and a first electric conductor layer 3 is formed on the exposed circuit element. Thereafter, an interlayer insulating film 4 is formed above the semiconductor substrate 1.

Then, a photosensitive resin layer 5 such as containing a chlorinated rubber or a phenol novolac is formed on the interlayer insulating film 4, and windows 6A are provided by a known photoetching technique, such that predetermined portions of the interlayer insulating film 4 are exposed.

The interlayer insulating film 4, which is exposed at the windows 6A, are selectively etched, so as to provide windows 6B. Then, the photosensitive resin layer 5 is removed using an etching solution that corrodes the photosensitive resin layer 5, but does not corrode the first electrically conductive layer 3 exposed at the windows 6B.

Using a known photoetching technique, a second electrically conductive layer 7 is formed, so as to provide electrical connection to the first electrically conductive layer 3. In the case of forming multilayer wiring structures having three or more layers, the foregoing steps are repeated to form the respective layers.

Then, using the photosensitive resin composition according to the present disclosure, windows 6C are opened by patternwise exposure, thereby forming a surface protective film 8. The surface protective film 8 protects the second electrically conductive layer 7 from external stress, α-rays, or the like, and the semiconductor device obtained has excellent reliability.

In the foregoing examples, the interlayer insulating film 4 may be formed using the photosensitive resin composition according to the present disclosure.

### EXAMPLES

More specific explanations according to the present disclosure are provided below with reference to examples and comparative examples. It should be noted that the present disclosure is not limited to the examples presented below.

### Examples 1 to 12 and Comparative Example 1

Ingredients indicated in Tables 1 and 2 in addition amounts indicated in Tables 1 and 2 were blended, so as to form uniform solutions. The obtained solutions were filtered through a membrane filter made of polytetrafluoroethylene (PTFE) having an aperture size of 1 μm, whereby photosensitive resin compositions of Examples 1 to 12 and Comparative Example 1 were obtained.

The addition amounts of respective ingredients indicated in Tables 1 and 2 are based on mass. In Tables 1 and 2, “-” means that the indicated ingredient was not contained.

TABLE 1

| | | Example | Example | Example | Example | Example | Example | Example |
|---|---|---|---|---|---|---|---|---|
| | | 1 | 2 | 3 | 4 | 5 | 6 | 7 |
| Unsaturated | I | 100 | 100 | 100 | 100 | 100 | 100 | 100 |
| Polyimide | | | | | | | | |
| Precursor | | | | | | | | |
| Solvent | | 180 | 180 | 180 | 180 | 180 | 180 | 180 |
| Crosslinking | I | 20 | — | — | — | — | — | — |
| Agent | II | — | 20 | — | — | — | — | — |
| | III | — | — | 20 | — | — | — | — |
| | IV | — | — | — | 20 | — | — | — |
| | V | — | — | — | — | 20 | — | — |
| | VI | — | — | — | — | — | 20 | — |
| | VII | — | — | — | — | — | — | 20 |
| | VIII | — | — | — | — | — | — | — |
| Stabilizer | | 0.3 | 0.3 | 0.3 | 0.3 | 0.3 | 0.3 | 0.3 |
| Photopolymerization | I | 4 | 4 | 4 | 4 | 4 | 4 | 4 |
| Initiator | II | — | — | — | — | — | — | — |
| | III | — | — | — | — | — | — | — |

| | | | | | | | |
|---|---|---|---|---|---|---|---|
| Sensitizer | 0.5 | 0.5 | 0.5 | 0.5 | 0.5 | 0.5 | 0.5 |
| UV Absorber | 1 | 1 | 1 | 1 | 1 | 1 | 1 |

TABLE 2

| | | Example | Example | Example | Example | Example | Comparative |
|---|---|---|---|---|---|---|---|
| | | 8 | 9 | 10 | 11 | 12 | Example 1 |
| Unsaturated | I | 100 | 100 | 100 | 100 | 100 | 100 |
| Polyimide | | | | | | | |
| Precursor | | | | | | | |
| Solvent | | 180 | 180 | 180 | 180 | 180 | 180 |
| Crosslinking | I | — | — | — | — | — | — |
| Agent | II | — | — | — | — | — | — |
| | III | — | — | — | — | — | — |
| | IV | — | — | — | — | — | — |
| | V | — | — | — | — | — | — |
| | VI | 10 | — | — | — | — | — |
| | VII | 10 | 15 | 7.5 | 20 | 20 | — |
| | VIII | — | — | — | — | — | 20 |
| Stabilizer | | 0.3 | 0.3 | 0.3 | 0.3 | 0.3 | 0.3 |
| Photopolymerization | I | 4 | 4 | 4 | — | — | 4 |
| Initiator | II | — | — | — | 4 | | — |
| | III | — | — | — | — | 9 | — |

| | | | | | | |
|---|---|---|---|---|---|---|
| Sensitizer | 0.5 | 0.5 | 0.5 | 0.5 | 1 | 0.5 |
| UV Absorber | 1 | 1 | 1 | 1 | 1 | 1 |

The details of the ingredients listed in Tables 1 and 2 are as follows.

### Unsaturated Polyimide Precursor 1

### (Synthesis of Polymer I)

380 g of N-methyl-2-pyrrolidone (NMP, Mitsubishi Chemical Corporation) was placed in a 2 L separable flask, and 47.08 g (152 mmol) of 4,4′-oxydiphthalic anhydride (OPDA, MANAC Incorporated) was added and dissolved with stirring. 0.24 g (2.1 mmol) of 1,4-diazabicyclo[2.2.2]octane (DABCO, Fujifilm Wako Pure Chemical Corporation) was further added and dissolved, and 5.54 g (42.6 mmol) of 2-hydroxyethyl methacrylate (HEMA, Fujifilm Wako Pure Chemical Corporation) was added. Thereafter, the solution was stirred at 30° C. for 1 hour, thereby obtaining a reaction solution. Separately, 27.4 g (129 mmol) of 2,2′-dimethylbiphenyl-4,4′-diamine (DMAP, Wakayama Seika Kogyo Co., Ltd.) was dissolved in 145 g of NMP, thereby preparing a DMAP solution.

The DMAP solution was dropwise added while the reaction solution was stirred at 35° C., and then stirred at 30° C. for 3 hours. Thereafter, 59.7 g (284 mmol) of trifluoroacetic anhydride (TFAA, Fujifilm Wako Pure Chemical Corporation) was dropwise added at 30° C. After the reaction solution was stirred at 45° C. for 2 hours, 0.08 g (0.74 mmol) of benzoquinone (BQ, Fujifilm Wako Pure Chemical Corporation) was added, and 40.4 g (310 mmol) of HEMA was dropwise added. After 15 hours of stirring, the reaction solution was cooled to room temperature. The reaction solution was poured into purified water, precipitates were collected and washed with purified water, and then dried under reduced pressure, thereby obtaining a polymer I as the unsaturated polyimide precursor I.

The weight average molecular weight (Mw) of the polymer I was 25,000.

The weight average molecular weight of the polymer was determined using the gel permeation chromatography method (GPC method), through calculation based on a calibration curve obtained using TSK gel standard polystyrene samples (Tosoh Corporation). The apparatus and conditions are shown below. The measurement sample was prepared by dissolving 2 mg of a sample in 1 mL of an eluent (tetrahydrofuran (THF)/dimethylformamide (DMF)=1/1 (v/v)), and then filtering the solution through a PTFE membrane filter having an aperture size of 1 μm.
Apparatus: PROMINENCE, manufactured by Shimadzu Corporation
Column: GELPAK GL S300MDT-5, manufactured by Resonac Corporation
Eluent: THF/DMF=1/1 (v/v), 0.03 mol/L lithium bromide, 0.06 mol/L phosphoric acid
Flow Rate: 1.0 mL/min
Measurement Wavelength: 270 nm
Injection Amount: 10 μL
Solvent: 3-methoxy-N,N′-dimethylpropanamide (product name KJCMPA-100, manufactured by KJ Chemicals Corporation)
Stabilizer: 1,4,4-trimethyl-2,3-diazabicyclo[3.2.2]non-2-ene-2,3-dioxide (TAOBN, Hampford Research Inc.)
Crosslinking Agents
I: glyoxal bis(diallylacetal)
II: 3,9-divinyl spirobi (m-dioxane)
III: TA-G (which reads on Formula (V) in which R³ is an allyl group, manufactured by Shikoku Chemicals Corporation)
IV: DD1 (which reads on Formula (V) in which R⁴ is an allyl group, manufactured by Shikoku Chemicals Corporation)
V: L-DAIC (which reads on Formula (V) in which two of R⁵'s are allyl groups, manufactured by Shikoku Chemicals Corporation)
VI: 1,2,4-trivinylcyclohexane
VII: allyl methacrylate
VIII: hexane-1,6-diol bis(2-methylacrylate)
Photopolymerization Initiators
I: 2-(benzoyloxyimino)-1-[4-(phenylthio)phenyl]-1-octanone (IRGACURE OXE 01, BASF Japan)
II: ethanone, 1-[9-ethyl-6-(2-methylbenzoyl)-9H-carbazole-3-yl]-, 1-(O-acetyloxime) (IRGACURE OXE 02, BASF Japan)
III: 1-phenyl-1,2-propanedione-2-(O-ethoxycarbonyl) oxime) (PDO, manufactured by Lambson Ltd.
Sensitizer: 4,4′-bis(diethylamino)benzophenone (EMK, Merck)
UV absorber: curcumin

### (Preparation of Cured Film)

The respective photosensitive resin compositions were applied to Si wafers according to the spin coating method using a coating and developing apparatus (ACT-8, Tokyo Electron Limited), and prebaked (PB) at 100° C. for 2 minutes and then at 110° C. for 2 minutes, thereby obtaining photosensitive resin films having film thicknesses varying from 5 to 15 μm.

The obtained photosensitive resin films were immersed in cyclopentanone, and the length of time that is from 0.5 times to twice the time required for complete dissolution was set as the development time.

Photosensitive resin films were prepared in the same manner as that described above, and the obtained photosensitive resin films were subjected to exposure through photomasks for via formation having diameters varying from 1 to 100 μm irradiated at exposure amounts indicated in Table 2, using an i-line stepper NES2W-06 (manufactured by Nikon Engineering Co., Ltd.).

The resin films after exposure were paddle-developed with cyclopentanone for the aforementioned development time, and subjected to rinsing with propyleneglycol monomethyl ether acetate (PGMEA), thereby obtaining patterned resin films.

### (Production of Patterned Cured Product)

The patterned resin films obtained were heated at 230° C. for 2 hours under nitrogen atmosphere in an inert gas oven INL-60N1-S (manufactured by Koyo Thermo Systems Co., Ltd.), thereby obtaining patterned cured products.

### (Evaluation of Resolution)

The patterned cured products obtained were each observed using an optical microscope, and the minimum mask size that resulted in formation of openings at which the area of the exposed substrate surface was 55% or more of the area of the via mask size was taken as the minimum mask aperture size.

The aspect ratio was calculated according to the following equation, and evaluated according to the following criteria.
Aspect Ratio=(Film Thickness after Curing/Minimum Mask Aperture Size)
A: aspect ratio was 1.0 or more
B: aspect ratio was from 0.8 to less than 1.0
C: aspect ratio was less than 0.8

TABLE 3

| | Example | Example | Example | Example | Example | Example | Example |
|---|---|---|---|---|---|---|---|
| | 1 | 2 | 3 | 4 | 5 | 6 | 7 |
| Film | 10 | 10 | 10 | 10 | 10 | 3 | 3 |
| Thickness | | | | | | | |
| (μm) | | | | | | | |
| Resolution | A | A | B | B | B | A | A |
| (μm) | | | | | | | |

TABLE 4

| | Exam- | Exam- | Exam- | Exam- | Exam- | Comparative |
|---|---|---|---|---|---|---|
| | ple 8 | ple 9 | ple 10 | ple 11 | ple 12 | Example 1 |
| Film | 3 | 3 | 3 | 3 | 3 | 3 |
| Thickness | | | | | | |
| (μm) | | | | | | |
| Resolution | A | A | A | A | A | C |
| (μm) | | | | | | |

As shown in Tables 3 and 4, the photosensitive resin compositions of Examples 1 to 12, which contained the vinyl crosslinking agent, exhibited higher resolution than that exhibited by the photosensitive resin composition of Comparative Example 1, which did not contain the vinyl crosslinking agent.

Further, it is surmised that photosensitive resin compositions containing the vinyl crosslinking agent exhibit a higher resolution than that exhibited by the photosensitive resin composition not containing the vinyl crosslinking agent, even in cases in which the Polymer I used as the unsaturated polyimide precursor in Example 1 is replaced by any one of polymers II to V.

### Polymer II

An unsaturated polyimide precursor formed from OPDA as an acid component and 4,4′-diaminodiphenyl ether (ODA) and m-phenylenediamine (MPD) in a molar ratio of 7:3 as amine components

### Polymer III

An unsaturated polyimide precursor formed from pyromellitic dianhydride (PMDA) and 4,4′-oxydiphthalic anhydride (ODPA) in a molar ratio of 3:1 as acid components and 2,2′-bis(trifluoromethyl)-4,4′-diaminobiphenyl (TFMB) as an amine component.

### Polymer IV

An unsaturated polyimide precursor formed from OPDA as an acid component and ODA as an amine component.

### Polymer V

An unsaturated polyimide precursor formed from 3,3′,4,4′-biphenyl tetracarboxylic dianhydride (s-BPDA) as an acid component and ODA as an amine component.

All publications, patent applications, and technical standards mentioned in this specification are herein incorporated by reference to the same extent as if each individual publication, patent application, or technical standard was specifically and individually indicated to be incorporated by reference.

### EXPLANATION OF REFERENCE CHARACTERS

1: Semiconductor Substrate
2: Protective Film
3: First Electrically Conductive Layer
4: Interlayer Insulating Film
5: Photosensitive Resin Layer
6A, 6B, 6C: Windows
7: Second Electrically Conductive Layer
8: Surface Protective Film

1. A photosensitive resin composition, comprising a polyimide precursor having a polymerizable unsaturated bond, and a crosslinking agent having a vinyl group accompanied by a hydrocarbon group located at an allyl position.

2. The photosensitive resin composition according to claim 1, wherein the polyimide precursor having a polymerizable unsaturated bond includes a structural unit represented by the following Formula (1): 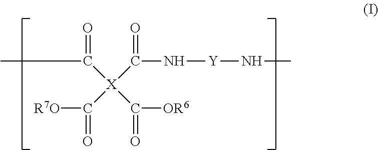
wherein, in Formula (1), X represents a tetravalent organic group; Y represents a divalent organic group; each of R⁶ and R⁷ independently represents a hydrogen atom or a monovalent organic group, and at least one of R⁶ or R⁷ has a polymerizable unsaturated bond.

3. The photosensitive resin composition according to claim 1, further comprising at least one selected from the group consisting of a photopolymerization initiator, a sensitizer, a ultraviolet absorber, a stabilizer, and a solvent.

4. A method of producing a patterned cured product, the method comprising:
applying the photosensitive resin composition according to claim 1 to a substrate, and drying the photosensitive resin composition, thereby forming a photosensitive resin film;
patternwise exposing the photosensitive resin film, thereby obtaining a resin film;
developing the resin film after patternwise exposure with a developer, thereby obtaining a patterned resin film, and
heating the patterned resin film.

5. A patterned cured product, which is obtained by curing the photosensitive resin composition according to claim 1.

6. The patterned cured product according to claim 5, wherein the patterned cured product is used as an interlayer insulating film, a cover-coat layer, or a surface protective film.

7. An electronic component, comprising the patterned cured product according to claim 5.
